(19) United States
(12) Patent Application Publication
(10) Pub. No.: US 2023/0303836 A1
(43) Pub. Date: Sep. 28, 2023

(54) POLYMER FILM AND LAMINATE

(71) Applicant: FUJIFILM Corporation, Tokyo (JP)

(72) Inventor: Yasuyuki SASADA, Shizuoka (JP)

(73) Assignee: FUJIFILM Corporation, Tokyo (JP)

(21) Appl. No.: 18/319,464

(22) Filed: May 17, 2023

Related U.S. Application Data
(63) Continuation of application No. PCT/JP2021/042909, filed on Nov. 24, 2021.

(30) Foreign Application Priority Data
Nov. 24, 2020 (JP) 2020-194652
Nov. 19, 2021 (JP) 2021-188870

(51) Int. Cl. C08L 71/12; C08J 5/18; B32B 7/025; B32B 15/20; B32B 15/09; B32B 27/36; B32B 27/20; H05K 1/03

(52) U.S. Cl. CPC C08L 71/123; C08J 5/18; B32B 7/025; B32B 15/20; B32B 15/09; B32B 27/36; B32B 27/20; H05K 1/0326; C08J 2371/12; C08J 2467/02; C08J 2427/18; B32B 2307/204; B32B 2307/748; B32B 2457/08; H05K 2201/0141

(57) ABSTRACT

Provided are a polymer film having excellent adhesiveness with a substrate, and a laminate using the polymer film. The polymer film contains a polymer having a dielectric loss tangent of 0.005 or less and a compound having a functional group, in which a concentration of the compound having a functional group is higher on at least one surface of the polymer film than inside of the polymer film.

### CROSS-REFERENCE TO RELATED APPLICATIONS

This application is a continuation application of International Application No. PCT/JP2021/042909, filed Nov. 24, 2021, the disclosure of which is incorporated herein by reference in its entirety. Further, this application claims priority from Japanese Patent Application No. 2020-194652, filed Nov. 24, 2020, and Japanese Patent Application No. 2021-188870, filed Nov. 19, 2021, the disclosures of which are incorporated herein by reference in their entireties.

### BACKGROUND OF THE INVENTION

### 1. Field of the Invention

The present disclosure relates to a polymer film and a laminate.

### 2. Description of the Related Art

In recent years, frequencies used in a communication equipment tend to be extremely high. In order to suppress transmission loss in a high frequency band, insulating materials used in a circuit board are required to have a lowered relative permittivity and a lowered dielectric loss tangent.

In the related art, polyimide is commonly used as the insulating material used in the circuit board, a liquid crystal polymer which has high heat resistance and low water absorption and is small in loss in the high frequency band has been attracted.

As a liquid crystal polymer film in the related art, for example, JP2020-26474A discloses a liquid crystalline polyester film that contains at least liquid crystalline polyester, in which, in a case where a first alignment degree is set to an alignment degree with respect to a first direction parallel to a main surface of the liquid crystalline polyester film, and a second alignment degree is set to an alignment degree with respect to a second direction parallel to the main surface and perpendicular to the first direction, a first alignment degree/second alignment degree that is a ratio of the first alignment degree and the second alignment degree is equal to or greater than 0.95 and equal to or less than 1.04, and a third alignment degree of the liquid crystalline polyester that is measured by a wide angle X-ray scattering method in a direction parallel to the main surface is equal to or greater than 60.0%.

In addition, as a functional film in the related art, a film disclosed in JP2018-5215A is known.

JP2018-5215A discloses a functional film containing a copolymer having a repeating unit represented by General Formula (I) and a repeating unit represented by General Formula (II) and/or a crosslinking reaction product derived from the copolymer.

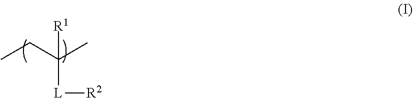

In General Formula (I), W represents a hydrogen atom or an alkyl group having 1 to 20 carbon atoms, R² represents an alkyl group having 1 to 20 carbon atoms, which has at least one fluorine atom as a substituent, or a group including —Si(R^{a3})(R^{a4})O—, and L represents —O—, —(C═O)O—, —O(C═O)—, or a divalent linking group composed of at least one selected from the group consisting of a divalent aliphatic chain group and a divalent aliphatic cyclic group. R^{a3} and R^{a4} each independently represent an alkyl group having 1 to 12 carbon atoms, which may have a substituent.

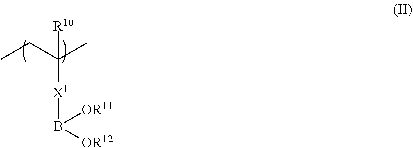

In General Formula (II), R¹⁰ represents a hydrogen atom or an alkyl group having 1 to 20 carbon atoms, R¹¹ and R¹² each independently represent a hydrogen atom, a substituted or unsubstituted aliphatic hydrocarbon group, a substituted or unsubstituted aryl group, or a substituted or unsubstituted heteroaryl group, and R¹¹ and R¹² may be linked to each other. X¹ represents a divalent linking group.

### SUMMARY OF THE INVENTION

An object to be achieved by an aspect of the present invention is to provide a polymer film having excellent adhesiveness with a substrate.

An object to be achieved by another aspect of the present invention is to provide a laminate using the above-described polymer film.

The methods for achieving the above-described objects include the following aspects.

<1> A polymer film comprising:
a polymer having a dielectric loss tangent of 0.005 or less; and
a compound having a functional group,
in which a concentration of the compound having a functional group is higher on at least one surface of the polymer film than inside of the polymer film.

<2> A polymer film comprising:
a polymer having a dielectric loss tangent of 0.005 or less; and
a compound having a functional group,
in which a surface coverage of the compound having a functional group on at least one surface of the polymer film is 50% by area or more.

<3> The polymer film according to <1> or <2>,
in which the functional group is at least one group selected from the group consisting of a covalent-bondable group, an ion-bondable group, a hydrogen-bondable group, and a dipole-interactable group.

<4> The polymer film according to <3>,
in which the functional group is a covalent-bondable group.

<5> The polymer film according to <4>,
in which the covalent-bondable group is at least one group selected from the group consisting of an epoxy group, an oxetanyl group, an isocyanate group, an acid anhydride group, a carbodiimide group, an N-hydroxy ester group, a glyoxal group, an imide ester group, a halogenated alkyl group, and a thiol group.

<6> The polymer film according to any one of <1> to <5>,
in which the compound having a functional group contains a silicon atom or a fluorine atom.

<7> The polymer film according to any one of <1> to <6>, further comprising:
a third component in which the compound having a functional group is immobilized to the polymer having a dielectric loss tangent of 0.005 or less.

<8> The polymer film according to <7>,
in which the third component includes a cured substance of a polyfunctional reactive compound.

<9> The polymer film according to <7> or <8>,
in which the third component contains a polymer which has a functional group interacting with the compound having a functional group and is compatible with the polymer having a dielectric loss tangent of 0.005 or less.

<10> The polymer film according to any one of <1> to <9>,
in which a difference between an SP value of the polymer having a dielectric loss tangent of 0.005 or less, which is determined by Hoy method, and an SP value of the compound having a functional group, which is determined by Hoy method, is 5 MPa0.5 or less.

<11> The polymer film according to any one of <1> to <10>,
in which the polymer film includes a layer A and a layer B on at least one surface of the layer A, and
the layer B contains the compound having a functional group.

<12> The polymer film according to <11>,
in which the layer B contains a third component in which the compound having a functional group is immobilized to the polymer having a dielectric loss tangent of 0.005 or less.

<13> The polymer film according to <12>,
in which a content of the third component in the layer B is higher than a content of the third component in the layer A.

<14> The polymer film according to any one of <11> to <13>,
wherein the polymer film further includes a layer C, and
the layer B, the layer A, and the layer C are provided in this order.

<15> The polymer film according to any one of <1> to <14>,
in which a linear expansion coefficient of the polymer film is −20 ppm/K to 50 ppm/K.

<16> The polymer film according to any one of <1> to <15>,
in which a dielectric loss tangent of the polymer film is 0.01 or less.

<17> The polymer film according to any one of <1> to <16>, further comprising:
a filler.

<18> The polymer film according to <17>,
in which a number density of the filler is higher inside the polymer film than on a surface of the polymer film.

<19> The polymer film according to any one of <1> to <18>,
in which the polymer having a dielectric loss tangent of 0.005 or less includes a liquid crystal polymer.

<20> The polymer film according to <19>,
in which the polymer having a dielectric loss tangent of 0.005 or less includes a liquid crystal polymer having a constitutional unit represented by any of Formulae (1) to (3),

—O-Ar¹-CO— Formula (1)

—CO-Ar²-CO— Formula (2)

—X-Ar³-Y— Formula (3)
in Formulae (1) to (3), Ar¹ represents a phenylene group, a naphthylene group, or a biphenylylene group, Ar² and Ar³ each independently represent a phenylene group, a naphthylene group, a biphenylylene group, or a group represented by Formula (4), X and Y each independently represent an oxygen atom or an imino group, and hydrogen atoms in Ar¹ to Ar³ may be each independently substituted with a halogen atom, an alkyl group, or an aryl group,

-Ar⁴-Z-Ar⁵- Formula (4)
in Formula (4), Ar⁴ and Ar⁵ each independently represent a phenylene group or a naphthylene group, and Z represents an oxygen atom, a sulfur atom, a carbonyl group, a sulfonyl group, or an alkylene group.

<21> A polymer film comprising:
a liquid crystal polymer; and
a compound having a functional group,
in which a concentration of the compound having a functional group is higher on at least one surface of the polymer film than inside of the polymer film.

<22> A polymer film comprising:
a liquid crystal polymer; and
a compound having a functional group,
in which a surface coverage of the compound having a functional group on at least one surface of the polymer film is 50% by area or more.

<23> A laminate comprising:
the polymer film according to any one of <1> to <22>; and
a metal layer disposed on a surface in which a concentration of the compound having a functional group in the polymer film is higher than inside of the polymer film.

<24> The laminate according to <23>,
in which the metal layers are respectively disposed on both surfaces of the polymer film.

<25> The laminate according to <23> or <24>,
in which the metal layer is a copper layer, and
a peel strength between the polymer film and the copper layer is 0.5 kN/m or more.

<26> The laminate according to any one of <23> to <25>,
in which the polymer film includes a layer A and a layer B on at least one surface of the layer A,
the layer B contains the compound having a functional group, and
the metal layer is disposed on the layer B.

According to the aspect of the present invention, it is possible to provide a polymer film having excellent adhesiveness with a substrate.

Further, according to another aspect of the present invention, it is possible to provide a laminate using the above-described polymer film.

### DESCRIPTION OF THE PREFERRED EMBODIMENTS

Hereinafter, the contents of the present disclosure will be described in detail. The description of configuration requirements below is made based on representative embodiments of the present disclosure in some cases, but the present disclosure is not limited to such embodiments.

Further, in the present specification, a numerical range shown using “to” indicates a range including numerical values described before and after “to” as a lower limit and an upper limit.

In a numerical range described in a stepwise manner in the present disclosure, an upper limit or a lower limit described in one numerical range may be replaced with an upper limit or a lower limit in another numerical range described in a stepwise manner. Further, in a numerical range described in the present disclosure, an upper limit or a lower limit described in the numerical range may be replaced with a value described in an example.

Further, in a case where substitution or unsubstitution is not noted in regard to the notation of a “group” (atomic group) in the present specification, the “group” includes not only a group that does not have a substituent but also a group having a substituent. For example, the concept of an “alkyl group” includes not only an alkyl group that does not have a substituent (unsubstituted alkyl group) but also an alkyl group having a substituent (substituted alkyl group).

In the present specification, the concept of “(meth)acryl” includes both acryl and methacryl, and the concept of “(meth)acryloyl” includes both acryloyl and methacryloyl.

Further, the term “step” in the present specification indicates not only an independent step but also a step which cannot be clearly distinguished from other steps as long as the intended purpose of the step is achieved.

Further, in the present disclosure, “% by mass” has the same definition as that for “% by weight”, and “part by mass” has the same definition as that for “part by weight”.

Furthermore, in the present disclosure, a combination of two or more preferred embodiments is a more preferred embodiment.

Further, the weight-average molecular weight (Mw) and the number-average molecular weight (Mn) in the present disclosure are molecular weights converted using polystyrene as a standard substance by performing detection with a gel permeation chromatography (GPC) analysis apparatus using TSKgel SuperHM-H (trade name, manufactured by Tosoh Corporation) column, a solvent of pentafluorophenol (PFP) and chloroform at a mass ratio of 1:2, and a differential refractometer, unless otherwise specified.

(Polymer Film)

A first embodiment of the polymer film according to the present disclosure contains a polymer having a dielectric loss tangent of 0.005 or less and a compound having a functional group, in which a concentration of the compound having a functional group is higher on at least one surface of the polymer film than inside of the polymer film.

A second embodiment of the polymer film according to the present disclosure contains a polymer having a dielectric loss tangent of 0.005 or less and a compound having a functional group, in which a surface coverage of the compound having a functional group on at least one surface of the polymer film is 50% by area or more.

A third embodiment of the polymer film according to the present disclosure contains a liquid crystal polymer and a compound having a functional group, in which a concentration of the compound having a functional group is higher on at least one surface of the polymer film than inside of the polymer film.

A fourth embodiment of the polymer film according to the present disclosure contains a liquid crystal polymer and a compound having a functional group, in which a surface coverage of the compound having a functional group on at least one surface of the polymer film is 50% by area or more.

In the present specification, the expression “polymer film according to the embodiment of the present disclosure” or “polymer film” denotes all the first embodiment, the second embodiment, the third embodiment, and the fourth embodiment described above, unless otherwise specified.

Many of the polymer films in the related art have high dielectric loss tangent. In addition, regarding a polymer film having low dielectric loss tangent among the polymer films in the related art, adhesiveness with a substrate (for example, a plastic film, a metal foil, or a metal wire) is insufficient.

As a result of intensive research conducted by the present inventor, it has been found that, with the above-described configuration, it is possible to provide a polymer film having excellent adhesiveness with the substrate.

The detailed mechanism for obtaining the above-described effects is not clear, but assumed as follows.

Since the polymer film contains a polymer having a dielectric loss tangent of 0.005 or less or a liquid crystal polymer and a compound having a functional group, in which a concentration of the compound having a functional group is higher on at least one surface of the polymer film than inside of the polymer film or a surface coverage of the compound having a functional group on at least one surface of the polymer film is 50% by area or more, even in a case where the polymer having a dielectric loss tangent of 0.005 or less or the liquid crystal polymer is used, the compound having a functional group is present on the surface of the polymer film and interacts with the substrate or a group existing on a surface of the substrate, so that it is presumed that the adhesiveness with the substrate is excellent.

In addition, although the compound having a functional group has a relatively high dielectric loss tangent, it is presumed that the total addition amount can be reduced by increasing the concentration in the surface, and a polymer film having good dielectric loss tangent is obtained.

In the first embodiment and third embodiment of the polymer film according to the present disclosure, the concentration of the above-described compound having a functional group is higher on at least one surface of the polymer film than inside of the polymer film, and from the viewpoint of dielectric loss tangent of the polymer film and adhesiveness with the metal layer, it is preferable that the concentration of the above-described compound having a functional group on at least one surface is 2 to 200 times higher than that on the inside, and it is more preferable that the concentration of the above-described compound having a functional group on at least one surface is 5 to 100 times higher than that on the inside.

In addition, in the second embodiment and fourth embodiment of the polymer film according to the present disclosure, from the viewpoint of dielectric loss tangent of the polymer film and adhesiveness with the metal layer, it is preferable that the concentration of the above-described compound having a functional group is higher on at least one surface of the polymer film than inside of the polymer film, it is more preferable that the concentration of the above-described compound having a functional group on at least one surface is 2 to 200 times higher than that on the inside, and it is particularly preferable that the concentration of the above-described compound having a functional group on at least one surface is 5 to 100 times higher than that on the inside.

In the present disclosure, a method for confirming the concentration of the compound having a functional group inside the polymer film and on the surface of the polymer film is as follows.

The polymer film is cut with a microtome to produce a cross-sectional sample of the polymer film in a thickness direction, and a distribution of each component in the polymer film in the thickness direction is measured for the cross section by Time-of-Flight Secondary Ion Mass Spectrometry (TOF-SIMS, determination device: TOF-SIMS V manufactured by ION-TOF).

Here, the surface of the polymer film refers to an outer surface (a surface in contact with air or the substrate) of the polymer film, and in the present disclosure, in a case where a thickness of the polymer film is 30 μm or less, the “surface” of the polymer film refers to a region from the outermost surface of the polymer film to a position corresponding to 10% thickness with respect to the thickness of the polymer film. In a case where the thickness of the polymer film is more than 30 μm, the “surface” refers to a region from the outermost surface of the polymer film to a position separated by 3 μm in the thickness direction.

In the present disclosure, in a case where the thickness of the polymer film is 30 μm or less, the “inside” of the polymer film refers to a region from the center of the polymer film in the thickness direction to a position corresponding to ±5% thickness with respect to the thickness of the polymer film. In a case where the thickness of the polymer film is more than 30 μm, the “inside” refers to a region from the center of the polymer film in the thickness direction to a position separated by ±1.5 μm in the thickness direction.

In the second embodiment and the fourth embodiment of the polymer film according to the present disclosure, the surface coverage of the above-described compound having a functional group on at least one surface of the polymer film is 50% by area or more, and from the viewpoint of dielectric loss tangent of the polymer film and adhesiveness with the metal layer, the surface coverage of the above-described compound having a functional group on at least one surface of the polymer film is preferably 50% by area to 100% by area.

In the first embodiment and the third embodiment of the polymer film according to the present disclosure, from the viewpoint of dielectric loss tangent of the polymer film and adhesiveness with the metal layer, the surface coverage of the above-described compound having a functional group on at least one surface of the polymer film is preferably 50% by area or more, more preferably 50% by area to 100% by area, and still more preferably 80% by area to 100% by area.

In the present disclosure, the surface coverage of the above-described compound having a functional group on the surface of the polymer film is measured by the following method.

A polymer film not containing the compound having a functional group and a compound having a functional group are prepared. Contact angles of the polymer film not containing the compound having a functional group and the compound having a functional group are measured, and each surface energy is calculated from the contact angle.

Similarly, surface energy of the polymer film to be measured is calculated.

A calibration curve is created using the surface energy of the polymer film not containing the compound having a functional group and the surface energy of the compound having a functional group.

The polymer film not containing the compound having a functional group corresponds to a polymer film having a surface coverage of 0% by area, and the compound having a functional group is a polymer film having a surface coverage of 100% by area.

From the created calibration curve, the surface coverage is calculated based on the surface energy of the polymer film to be measured.

The surface energy can be obtained by conditioning for 24 hours at 25° C. and a relative humidity of 60%, measuring the contact angle to water and methylene iodide, and calculating the surface energy using Owens method based on the measured contact angle. The contact angle can be measured, for example, using DM901 (manufactured by Kyowa Interface Science Co., Ltd., contact angle meter).

In a case where the polymer film not containing the compound having a functional group cannot be prepared, the surface coverage can also be obtained by performing imaging analysis on the surface of the polymer film and measuring a coverage area of a fragment derived from the compound having a functional group.

<Polymer Having Dielectric Loss Tangent of 0.005 or Less>

The polymer film according to the embodiment of the present disclosure contains a polymer having a dielectric loss tangent of 0.005 or less.

The dielectric loss tangent of 0.005 or less indicates that the degree of electrical energy loss is small. From the viewpoint of dielectric loss tangent of the polymer film and adhesiveness with the metal layer, the dielectric loss tangent of the polymer is preferably 0.004 or less, more preferably 0.0035 or less, and particularly preferably 0.003 or less. The lower limit value of the dielectric loss tangent of the polymer is not particularly limited, but is, for example, more than 0.

In the present disclosure, the measurement of the dielectric loss tangent of the polymer is carried out according to the following method of measuring a dielectric loss tangent by identifying or isolating a chemical structure of the polymer constituting each layer and using a powdered sample of the polymer to be measured.

The dielectric loss tangent in the present disclosure is measured by the following method.

The dielectric loss tangent is measured by a resonance perturbation method at a frequency of 10 GHz. A 1 GHz cavity resonator (“CP531” manufactured by Kanto Electronics Application & Development Inc.) is connected to a network analyzer (“E8363B” manufactured by Agilent Technology), a sample (width: 2.0 mm×length: 80 mm) of the film is inserted into the cavity resonator, and the dielectric loss tangent of the sample is measured based on a change in resonance frequency for 96 hours before and after the insertion in an environment of a temperature of 25° C. and a humidity of 60% RH.

In a case where a dielectric loss tangent of each layer included in the polymer film is measured, an unnecessary layer may be scraped off with a razor or the like to prepare an evaluation sample of only the target layer.

A weight-average molecular weight Mw of the polymer having a dielectric loss tangent of 0.005 or less is preferably 1,000 or more, more preferably 2,000 or more, and particularly preferably 5,000 or more. In addition, the weight-average molecular weight Mw of the polymer having a dielectric loss tangent of 0.005 or less is preferably 1,000,000 or less, more preferably 300,000 or less, and particularly preferably less than 100,000.

From the viewpoint of dielectric loss tangent of the polymer film, adhesiveness with the metal layer, and heat resistance, a melting point Tm or a 5%-by-mass-loss temperature Td of the polymer having a dielectric loss tangent of 0.005 or less is preferably 200° C. or higher, more preferably 250° C. or higher, still more preferably 280° C. or higher, and particularly preferably 300° C. or higher. The upper limit value of Tm or Td is not particularly limited, but Tm or Td is, for example, 500° C. or lower, preferably 420° C. or lower.

The melting point Tm in the present disclosure is defined as a value measured by a differential scanning calorimetry (DSC) device.

In addition, the 5%-by-mass-loss temperature Td in the present disclosure is measured with a thermogravimetric analysis (TGA) device. Specifically, a weight of the sample put into the measurement pan is defined as an initial value, and a temperature at which the weight is reduced by 5% by mass with respect to the initial value due to the heating is defined as the 5%-by-mass-loss temperature Td.

From the viewpoint of dielectric loss tangent of the polymer film, adhesiveness with the metal layer, and heat resistance, a glass transition temperature Tg of the polymer having a dielectric loss tangent of 0.005 or less is preferably 150° C. or higher, and more preferably 200° C. or higher. The upper limit value of Tg is not particularly limited, but Tg is, for example, lower than 350° C., preferably lower than 280° C. and more preferably 280° C. or lower.

The glass transition temperature Tg in the present disclosure is defined as a value measured by a differential scanning calorimetry (DSC) device.

In the present disclosure, the type of the polymer having a dielectric loss tangent of 0.005 or less is not particularly limited, and a known polymer can be used.

Examples of the polymer having a dielectric loss tangent of 0.005 or less include thermoplastic resins such as a liquid crystal polymer, a fluorine-based polymer, a polymerized substance of a compound which has a cyclic aliphatic hydrocarbon group and a group having an ethylenically unsaturated bond, polyether ether ketone, polyolefin, polyamide, polyester, polyphenylene sulfide, polyether ketone, polycarbonate, polyethersulfone, polyphenylene ether and a modified product thereof, and polyetherimide; elastomers such as a copolymer of glycidyl methacrylate and polyethylene; and thermosetting resins such as a phenol resin, an epoxy resin, a polyimide resin, and a cyanate resin.

Among these, as the polymer having a dielectric loss tangent of 0.005 or less, from the viewpoint of dielectric loss tangent of the polymer film, adhesiveness with the metal layer, and heat resistance, at least one polymer selected from the group consisting of a liquid crystal polymer, a fluorine-based polymer, a polymerized substance of a compound which has a cyclic aliphatic hydrocarbon group and a group having an ethylenically unsaturated bond, and polyether ether ketone is preferable, and at least one polymer selected from the group consisting of a liquid crystal polymer and a fluorine-based polymer is more preferable, and a liquid crystal polymer is particularly preferable from the viewpoint of dielectric loss tangent of the polymer film; and from the viewpoint of heat resistance and mechanical strength, a fluorine-based polymer is preferable.

-Liquid Crystal Polymer-

The liquid crystal polymer contained in the polymer film according to the embodiment of the present disclosure preferably has a dielectric loss tangent of 0.01 or less, and from the viewpoint of dielectric loss tangent of the polymer film, a liquid crystal polymer having a dielectric loss tangent of 0.005 or less is preferable.

In the present disclosure, the type of the liquid crystal polymer used as the polymer having a dielectric loss tangent of 0.005 or less is not particularly limited as long as the dielectric loss tangent thereof is 0.005 or less, and a known liquid crystal polymer can be used.

In addition, the liquid crystal polymer may be a thermotropic liquid crystal polymer which exhibits liquid crystallinity in a molten state, or may be a lyotropic liquid crystal polymer which exhibits liquid crystallinity in a solution state. Further, in a case where the liquid crystal polymer is a thermotropic liquid crystal polymer, the liquid crystal polymer is preferably a liquid crystal polymer which is molten at a temperature of 450° C. or lower.

Examples of the liquid crystal polymer include a liquid crystal polyester, a liquid crystal polyester amide in which an amide bond is introduced into the liquid crystal polyester, a liquid crystal polyester ether in which an ether bond is introduced into the liquid crystal polyester, and a liquid crystal polyester carbonate in which a carbonate bond is introduced into the liquid crystal polyester.

In addition, as the liquid crystal polymer, from the viewpoint of liquid crystallinity and linear expansion coefficient, a polymer having an aromatic ring is preferable, and an aromatic polyester or an aromatic polyester amide is more preferable.

Further, the liquid crystal polymer may be a polymer in which an imide bond, a carbodiimide bond, a bond derived from an isocyanate, such as an isocyanurate bond, or the like is further introduced into the aromatic polyester or the aromatic polyester amide.

Further, it is preferable that the liquid crystal polymer is a wholly aromatic liquid crystal polymer formed of only an aromatic compound as a raw material monomer.

Examples of the liquid crystal polymer include the following liquid crystal polymers.
1) a liquid crystal polymer obtained by polycondensing (i) an aromatic hydroxycarboxylic acid, (ii) an aromatic dicarboxylic acid, and (iii) at least one compound selected from the group consisting of an aromatic diol, an aromatic hydroxyamine, and an aromatic diamine;
2) a liquid crystal polymer obtained by polycondensing a plurality of types of aromatic hydroxycarboxylic acids;
3) a liquid crystal polymer obtained by polycondensing (i) an aromatic dicarboxylic acid and (ii) at least one compound selected from the group consisting of an aromatic diol, an aromatic hydroxyamine, and an aromatic diamine;
4) a liquid crystal polymer obtained by polycondensing (i) polyester such as polyethylene terephthalate and (ii) an aromatic hydroxycarboxylic acid.

Here, the aromatic hydroxycarboxylic acid, the aromatic dicarboxylic acid, the aromatic diol, the aromatic hydroxyamine, and the aromatic diamine may be each independently replaced with a polycondensable derivative.

For example, the aromatic hydroxycarboxylic acid and the aromatic dicarboxylic acid can be replaced with aromatic hydroxycarboxylic acid ester and aromatic dicarboxylic acid ester, by converting a carboxy group into an alkoxycarbonyl group or an aryloxycarbonyl group.

The aromatic hydroxycarboxylic acid and the aromatic dicarboxylic acid can be replaced with aromatic hydroxycarboxylic acid halide and aromatic dicarboxylic acid halide, by converting a carboxy group into a haloformyl group.

The aromatic hydroxycarboxylic acid and the aromatic dicarboxylic acid can be replaced with aromatic hydroxycarboxylic acid anhydride and aromatic dicarboxylic acid anhydride, by converting a carboxy group into an acyloxycarbonyl group.

Examples of a polymerizable derivative of a compound having a hydroxy group, such as an aromatic hydroxycarboxylic acid, an aromatic diol, and an aromatic hydroxyamine, include a derivative (acylated product) obtained by acylating a hydroxy group and converting the acylated group into an acyloxy group.

For example, the aromatic hydroxycarboxylic acid, the aromatic diol, and the aromatic hydroxyamine can be each replaced with an acylated product by acylating a hydroxy group and converting the acylated group into an acyloxy group.

Examples of a polymerizable derivative of a compound having an amino group, such as an aromatic hydroxyamine or an aromatic diamine, include a derivative (acylated product) obtained by acylating an amino group and converting the acylated group to an acylamino group.

For example, the aromatic hydroxyamine and the aromatic diamine can be each replaced with an acylated product by acylating an amino group and converting the acylated group into an acylamino group.

From the viewpoint of liquid crystallinity, dielectric loss tangent of the polymer film, and adhesiveness with the metal layer, the liquid crystal polymer preferably has a constitutional unit represented by any of Formulae (1) to (3), more preferably has a constitutional unit represented by Formula (1), and particularly preferably has a constitutional unit represented by Formula (1), a constitutional unit represented by Formula (2), and a constitutional unit represented by Formula (3). Hereinafter, the constitutional unit represented by Formula (1) and the like are also referred to as “unit (1)” and the like.

—O-Ar¹-CO— Formula (1)

—CO-Ar²-CO— Formula (2)

—X-Ar³-Y— Formula (3)

In Formulae (1) to (3), Ar¹ represents a phenylene group, a naphthylene group, or a biphenylylene group, Ar² and Ar³ each independently represent a phenylene group, a naphthylene group, a biphenylylene group, or a group represented by Formula (4), X and Y each independently represent an oxygen atom or an imino group, and hydrogen atoms in Ar¹ to Ar³ may be each independently substituted with a halogen atom, an alkyl group, or an aryl group.

-Ar⁴-Z-Ar⁵- Formula (4)

In Formula (4), Ar⁴ and Ar⁵ each independently represent a phenylene group or a naphthylene group, and Z represents an oxygen atom, a sulfur atom, a carbonyl group, a sulfonyl group, or an alkylene group.

Examples of the halogen atom include a fluorine atom, a chlorine atom, a bromine atom, and an iodine atom.

Examples of the alkyl group include a methyl group, an ethyl group, an n-propyl group, an isopropyl group, an n-butyl group, an isobutyl group, an s-butyl group, a t-butyl group, an n-hexyl group, a 2-ethylhexyl group, an n-octyl group, and an n-decyl group. The number of carbon atoms in the alkyl group is preferably 1 to 10.

Examples of the aryl group include a phenyl group, an o-tolyl group, an m-tolyl group, a p-tolyl group, a 1-naphthyl group, and a 2-naphthyl group. The number of carbon atoms in the aryl group is preferably 6 to 20.

In a case where the hydrogen atom in Ar¹ to Ar³ is substituted with a halogen atom, an alkyl group, or an aryl group, the number of each of substituents in Ar¹, Ar², and Ar³ independently is preferably 2 or less and more preferably 1.

Examples of the alkylene group include a methylene group, a 1,1-ethanediyl group, a 1-methyl-1,1-ethanediyl group, a 1,1-butanediyl group, and a 2-ethyl-1,1-hexanediyl group. The number of carbon atoms in the alkylene group is preferably 1 to 10.

The unit (1) is a constitutional unit derived from an aromatic hydroxycarboxylic acid.

Preferred examples of the unit (1) include an aspect in which Ar¹ represents a p-phenylene group (constitutional unit derived from p-hydroxybenzoic acid), an aspect in which Ar¹ represents a 2,6-naphthylene group (constitutional unit derived from 6-hydroxy-2-naphthoic acid), and an aspect in which Ar¹ represents a 4,4′-biphenylylene group (constitutional unit derived from 4′-hydroxy-4-biphenylcarboxylic acid).

The unit (2) is a constitutional unit derived from an aromatic dicarboxylic acid.

Preferred examples of the unit (2) include an aspect in which Ar² represents a p-phenylene group (constitutional unit derived from terephthalic acid), an aspect in which Ar² represents an m-phenylene group (constitutional unit derived from isophthalic acid), an aspect in which Ar² represents a 2,6-naphthylene group (constitutional unit derived from 2,6-naphthalenedicarboxylic acid), and an aspect in which Ar² represents a diphenylether-4,4′-diyl group (constitutional unit derived from diphenylether-4,4′-dicarboxylic acid).

The unit (3) is a constitutional unit derived from an aromatic diol, an aromatic hydroxylamine, or an aromatic diamine.

Preferred examples of the unit (3) include an aspect in which Ar³ represents a p-phenylene group (constitutional unit derived from hydroquinone, p-aminophenol, or p-phenylenediamine), an aspect in which Ar³ represents an m-phenylene group (constitutional unit derived from isophthalic acid), and an aspect in which Ar³ represents a 4,4′-biphenylylene group (constitutional unit derived from 4,4′-dihydroxybiphenyl, 4-amino-4′-hydroxybiphenyl, or 4,4′ -diaminobiphenyl).

The content of the unit (1) is preferably 30% by mole or more, more preferably 30% by mole to 80% by mole, still more preferably 30% by mole to 60% by mole, and particularly preferably 30% by mole to 40% by mole with respect to the total amount of all constitutional units.

The content of the unit (2) is preferably 35% by mole or less, more preferably 10% by mole to 35% by mole, still more preferably 20% by mole to 35% by mole, and particularly preferably 30% by mole to 35% by mole with respect to the total amount of all constitutional units.

The content of the unit (3) is preferably 35% by mole or less, more preferably 10% by mole to 35% by mole, still more preferably 20% by mole to 35% by mole, and particularly preferably 30% by mole to 35% by mole with respect to the total amount of all constitutional units.

The heat resistance, the strength, and the rigidity are likely to be improved as the content of the unit (1) increases, but the solubility in a solvent is likely to be decreased in a case where the content thereof is too large.

The total amount of all constitutional units is a value obtained by totaling a substance amount (mol) of each constitutional unit. The substance amount of each constitutional unit is calculated by dividing a mass of each constitutional unit constituting the liquid crystal polymer by a formula weight of each constitutional unit.

In a case where a ratio of the content of the unit (2) to the content of the unit (3) is expressed as [content of unit (2)]/[content of unit (3)] (mol/mol), the ratio is preferably 0.9/1 to 1/0.9, more preferably 0.95/1 to 1/0.95, and still more preferably 0.98/1 to 1/0.98.

The liquid crystal polymer may have two or more kinds of each of the units (1) to (3) independently. In addition, the liquid crystal polymer may have a constitutional unit other than the units (1) to (3). A content of other constitutional units is preferably 10% by mole or less and more preferably 5% by mole or less with respect to the total amount of all constitutional units.

Since the solubility in a solvent is excellent, the liquid crystal polymer preferably has a unit (3) in which at least one of X or Y is an imino group, that is, preferably has at least one of a constitutional unit derived from an aromatic hydroxylamine or a constitutional unit derived from an aromatic diamine, and it is more preferable to have only a unit (3) in which at least one of X or Y is an imino group.

It is preferable that the liquid crystal polymer is produced by melt-polymerizing raw material monomers corresponding to the constitutional units constituting the liquid crystal polymer. The melt polymerization may be carried out in the presence of a catalyst. Examples of the catalyst include metal compounds such as magnesium acetate, stannous acetate, tetrabutyl titanate, lead acetate, sodium acetate, potassium acetate, and antimony trioxide, and nitrogen-containing heterocyclic compounds such as 4-(dimethylamino)pyridine and 1-methylimidazole. The catalyst is preferably a nitrogen-containing heterocyclic compound. The melt polymerization may be further carried out by solid phase polymerization as necessary.

A flow start temperature of the liquid crystal polymer is preferably 180° C. or higher, more preferably 200° C. or higher, and still more preferably 250° C. or higher. The flow start temperature thereof is preferably 350° C. or lower, more preferably 330° C. or lower, and still more preferably 310° C. or lower. In a case where the flow start temperature of the liquid crystal polymer is within the above-described range, the solubility, the heat resistance, the strength, and the rigidity are excellent, and the viscosity of the solution is appropriate.

The flow start temperature, also referred to as a flow temperature, is a temperature at which a viscosity of 4,800 Pa·s (48,000 poises) is exhibited in a case where the liquid crystal polymer is melted and extruded from a nozzle having an inner diameter of 1 mm and a length of 10 mm while the temperature is raised at a rate of 4° C./min under a load of 9.8 MPa (100 kg/cm²) using a capillary rheometer and is a guideline for the molecular weight of the liquid crystal polyester (see p. 95 of “Liquid Crystal Polymers-Synthesis/Molding/Applications-”, written by Naoyuki Koide, CMC Corporation, Jun. 5, 1987).

In addition, a weight-average molecular weight of the liquid crystal polymer is preferably 1,000,000 or less, more preferably 3,000 to 300,000, still more preferably 5,000 to 100,000, and particularly preferably 5,000 to 30,000. In a case where the weight-average molecular weight of the liquid crystal polymer is within the above-described range, a film after heat treatment is excellent in thermal conductivity, heat resistance, strength, and rigidity in the thickness direction.

-Fluorine-Based Polymer-

From the viewpoint of heat resistance and mechanical strength, the polymer having a dielectric loss tangent of 0.005 or less is preferably a fluorine-based polymer.

In the present disclosure, the type of the fluorine-based polymer used as the polymer having a dielectric loss tangent of 0.005 or less is not particularly limited as long as the dielectric loss tangent thereof is 0.005 or less, and a known fluorine-based polymer can be used.

In addition, examples of the fluorine-based polymer include a homopolymer and a copolymer containing a constitutional unit derived from a fluorinated α-olefin monomer, that is, an α-olefin monomer containing at least one fluorine atom. In addition, examples of the fluorine-based polymer include a copolymer containing a constitutional unit derived from a fluorinated α-olefin monomer, and a constitutional unit derived from a non-fluorinated ethylenically unsaturated monomer reactive to the fluorinated α-olefin monomer.

Examples of the fluorinated a-olefin monomer include CF₂═CF₂, CHF═CF₂, CH₂═CF₂, CHCl═CHF, CClF═CF₂, CCl₂═CF₂, CClF═CClF, CHF═CCl₂, CH₂═CClF, CCl₂═CClF, CF₃CF═CF₂, CF₃CF═CHF, CF₃CH═CF₂, CF₃CH═CH₂, CHF₂CH═CHF, CF₃CF═CF₂, and perfluoro(alkyl having 2 to 8 carbon atoms) vinyl ether (for example, perfluoromethyl vinyl ether, perfluoropropyl vinyl ether, and perfluorooctyl vinyl ether). Among these, as the fluorinated α-olefin monomer, at least one monomer selected from the group consisting of tetrafluoroethylene (CF₂═CF₂), chlorotrifluoroethylene (CClF═CF₂), (perfluorobutyl)ethylene, vinylidene fluoride (CH₂═CF₂), and hexafluoropropylene (CF₂═CFCF₃) is preferable.

Examples of the non-fluorinated ethylenically unsaturated monomer include ethylene, propylene, butene, and an ethylenically unsaturated aromatic monomer (for example, styrene and α-methylstyrene).

The fluorinated α-olefin monomer may be used alone or in combination of two or more thereof.

In addition, the non-fluorinated ethylenically unsaturated monomer may be used alone or in combination of two or more thereof.

Examples of the fluorine-based polymer include polychlorotrifluoroethylene (PCTFE), poly(chlorotrifluoroethylene-propylene), poly(ethylene-tetrafluoroethylene) (ETFE), poly(ethylene-chlorotrifluoroethylene) (ECTFE), poly(hexafluoropropylene), poly(tetrafluoroethylene) (PTFE), poly(tetrafluoroethylene-ethylene-propylene), poly(tetrafluoroethylene-hexafluoropropylene) (FEP), poly(tetrafluoroethylene-propylene) (FEPM), poly(tetrafluoroethylene-perfluoropropylene vinyl ether), poly(tetrafluoroethylene-perfluoroalkyl vinyl ether) (PFA) (for example, poly(tetrafluoroethylene-perfluoropropyl vinyl ether)), polyvinyl fluoride (PVF), polyvinylidene fluoride (PVDF), poly(vinylidene fluoride-chlorotrifluoroethylene), perfluoropolyether, perfluorosulfonic acid, and perfluoropolyoxetane.

The fluorine-based polymer may have a constitutional unit derived from fluorinated ethylene or fluorinated propylene.

The fluorine-based polymer may be used alone or in combination of two or more thereof.

The fluorine-based polymer is preferably FEP, PFA, ETFE, or PTFE.

The FEP is available from Du Pont as the trade name of TEFLON (registered trademark) FEP or from DAIKIN INDUSTRIES, LTD. as the trade name of NEOFLON FEP. The PFA is available from DAIKIN INDUSTRIES, LTD. as the trade name of NEOFLON PFA, from Du Pont as the trade name of TEFLON (registered trademark) PFA, or from Solvay Solexis as the trade name of HYFLON PFA.

The fluorine-based polymer more preferably includes PTFE. The PTFE may be a PTFE homopolymer, a partially modified PTFE homopolymer, or a combination including one or both of these. The partially modified PTFE homopolymer preferably contains a constitutional unit derived from a comonomer other than tetrafluoroethylene in an amount of less than 1% by mass based on the total mass of the polymer.

The fluorine-based polymer may be a crosslinkable fluoropolymer having a crosslinkable group. The crosslinkable fluoropolymer can be crosslinked by a known crosslinking method in the related art. One of the representative crosslinkable fluoropolymers is a fluoropolymer having a (meth)acryloyloxy group. For example, the crosslinkable fluoropolymer can be represented by Formula:

H₂C═CR′COO—(CH₂)ₙ—R—(CH₂)ₙ—OOCR′═CH₂

In the formula, R is an oligomer chain having a constitutional unit derived from the fluorinated α-olefin monomer, R′ is H or —CH₃, and n is 1 to 4. R may be a fluorine-based oligomer chain having a constitutional unit derived from tetrafluoroethylene.

In order to initiate a radical crosslinking reaction through the (meth)acryloyloxy group in the fluorine-based polymer, by exposing the fluoropolymer having a (meth)acryloyloxy group to a free radical source, a crosslinked fluoropolymer network can be formed. The free radical source is not particularly limited, and suitable examples thereof include a photoradical polymerization initiator and an organic peroxide. Appropriate photoradical polymerization initiators and organic peroxides are well known in the art. The crosslinkable fluoropolymer is commercially available, and examples thereof include Viton B manufactured by Du Pont.

-Polymerized Substance of Compound Which Has Cyclic Aliphatic Hydrocarbon Group and Group Having Ethylenically Unsaturated Bond-

The polymer having a dielectric loss tangent of 0.005 or less may be a polymerized substance of a compound which has a cyclic aliphatic hydrocarbon group and a group having an ethylenically unsaturated bond.

Examples of the polymerized substance of a compound which has a cyclic aliphatic hydrocarbon group and a group having an ethylenically unsaturated bond include thermoplastic resins having a constitutional unit derived from a cyclic olefin monomer such as norbornene and a polycyclic norbornene-based monomer.

The polymerized substance of a compound which has a cyclic aliphatic hydrocarbon group and a group having an ethylenically unsaturated bond may be a ring-opened polymer of the above-described cyclic olefin, a hydrogenated product of a ring-opened copolymer using two or more cyclic olefins, or an addition polymer of a cyclic olefin and a linear olefin or aromatic compound having an ethylenically unsaturated bond such as a vinyl group. In addition, a polar group may be introduced into the polymerized substance of a compound which has a cyclic aliphatic hydrocarbon group and a group having an ethylenically unsaturated bond.

The polymerized substance of a compound which has a cyclic aliphatic hydrocarbon group and a group having an ethylenically unsaturated bond may be used alone or in combination of two or more thereof.

A ring structure of the cyclic aliphatic hydrocarbon group may be a single ring, a fused ring in which two or more rings are fused, or a crosslinked ring.

Examples of the ring structure of the cyclic aliphatic hydrocarbon group include a cyclopentane ring, a cyclohexane ring, a cyclooctane ring, an isophorone ring, a norbornane ring, and a dicyclopentane ring.

The compound which has a cyclic aliphatic hydrocarbon group and a group having an ethylenically unsaturated bond may be a monofunctional ethylenically unsaturated compound or a polyfunctional ethylenically unsaturated compound.

The number of cyclic aliphatic hydrocarbon groups in the compound which has a cyclic aliphatic hydrocarbon group and a group having an ethylenically unsaturated bond may be 1 or more, and may be 2 or more.

It is sufficient that the polymerized substance of a compound which has a cyclic aliphatic hydrocarbon group and a group having an ethylenically unsaturated bond is a polymer obtained by polymerizing at least one compound which has a cyclic aliphatic hydrocarbon group and a group having an ethylenically unsaturated bond, and it may be a polymerized substance of two or more kinds of the compound which has a cyclic aliphatic hydrocarbon group and a group having an ethylenically unsaturated bond or a copolymer with other ethylenically unsaturated compounds having no cyclic aliphatic hydrocarbon group.

In addition, the polymerized substance of a compound which has a cyclic aliphatic hydrocarbon group and a group having an ethylenically unsaturated bond is preferably a cycloolefin polymer.

-Polyether Ether Ketone-

The polymer having a dielectric loss tangent of 0.005 or less may be a polyether ether ketone.

The polyether ether ketone is one type of the aromatic polyether ketone, and is a polymer in which bonds are arranged in the order of an ether bond, an ether bond, and a carbonyl bond (ketone). It is preferable that the bonds are linked to each other by a divalent aromatic group.

In the present disclosure, the type of the polyether ether ketone used as the polymer having a dielectric loss tangent of 0.005 or less is not particularly limited as long as the polyether ether ketone has a dielectric loss tangent of 0.005 or less, and a known polyether ether ketone can be used.

The polymer having a dielectric loss tangent of 0.005 or less is preferably a polymer soluble in a specific organic solvent (hereinafter, also referred to as “soluble polymer”).

Specifically, the soluble polymer in the present disclosure is a polymer in which 0.1 g or more thereof is dissolved at 25° C. in 100 g of at least one solvent selected from the group consisting of N-methylpyrrolidone, N-ethylpyrrolidone, dichloromethane, dichloroethane, chloroform, N-methyl-2-pyrrolidone, N,N-dimethylacetamide, γ-butyrolactone, dimethylformamide, ethylene glycol monobutyl ether, and ethylene glycol monoethyl ether.

The polymer film may contain only one kind of the polymer having a dielectric loss tangent of 0.005 or less, or may contain two or more kinds thereof.

From the viewpoint of dielectric loss tangent of the polymer film and adhesiveness with the metal layer, the content of the polymer having a dielectric loss tangent of 0.005 or less in the polymer film is preferably 20% by mass to 99% by mass, more preferably 30% by mass to 98% by mass, still more preferably 40% by mass to 97% by mass, and particularly preferably 50% by mass to 95% by mass with respect to the total mass of the polymer film.

<Compound Having Functional Group>

The polymer film according to the embodiment of the present disclosure contains a compound having a functional group.

In the first embodiment and the second embodiment, the compound having a functional group in the present disclosure is a compound other than the above-described polymer having a dielectric loss tangent of 0.005 or less. In the third embodiment and the fourth embodiment, the compound having a functional group in the present disclosure is a compound other than the above-described liquid crystal polymer.

The compound having a functional group may be a low-molecular-weight compound, an oligomer, or a polymer, but from the viewpoint of mechanical strength, an oligomer or a polymer is preferable, and a polymer is more preferable. For example, the polymer film according to the embodiment of the present disclosure may contain a polymer having a functional group as the compound having a functional group.

In the present disclosure, the oligomer is a polymerized substance having a weight-average molecular weight of less than 2,000, and the polymer is a polymerized substance having a weight-average molecular weight of 2,000 or more.

The above-described functional group is preferably a group capable of interacting with a metal or a group existing on a surface of the metal.

In addition, the above-described functional group is preferably at least one group selected from the group consisting of a covalent-bondable group, an ion-bondable group, a hydrogen-bondable group, and a dipole-interactable group.

From the viewpoint of compatibility between the polymer having a dielectric loss tangent of 0.005 or less or the liquid crystal polymer and the compound having a functional group and viewpoint of dielectric loss tangent of the polymer film, the compound having a functional group is preferably a low-molecular-weight compound, and from the viewpoint of heat resistance of the polymer film, mechanical strength, and surface maldistribution, the compound having a functional group is preferably an oligomer or a polymer.

It is preferable that the compound having a functional group interacts with a matrix material (for example, the polymer having a dielectric loss tangent of 0.005 or less) contained in the polymer film, or forms an entanglement. Examples of the entanglement include an aspect in which the compound having a functional group and the matrix material are mixed at a molecular level to increase friction coefficient, an aspect in which a continuous phase of the compound having a functional group and a continuous phase of the matrix material interpenetrate each other, and an aspect (anchor effect) in which a mechanical bond is formed due to a surface shape of each material.

In the aspect in which the compound having a functional group and the matrix material interpenetrate each other, it is preferable that the compound having a functional group is a compound which phase-separates from the matrix material, or is a compound which phase-separates from the matrix material due to bonding between the compounds having a functional group.

It is sufficient that the number of functional groups in the compound having a functional group is 1 or more, and the number thereof may be 2 or more.

In addition, the compound having a functional group may have only one kind of functional group, or two or more kinds of functional groups.

Among these, the number of functional groups in the compound having a functional group is preferably 2 or more. As the number of functional groups increases, electrical characteristics tend to decrease, so that it is preferable that the number of functional groups is 10 or less.

From the viewpoint of adhesiveness with the metal layer, a molecular weight of the low-molecular-weight compound used as the compound having a functional group is preferably 50 or more and less than 2,000, more preferably 100 or more and less than 1,000, and particularly preferably 200 or more and less than 1,000.

In addition, from the viewpoint of adhesiveness with the metal layer and surface maldistribution, a weight-average molecular weight of the high-molecular-weight compound (oligomer and polymer) used as the compound having a functional group is preferably 1,000 or more, more preferably 2,000 or more, still more preferably 3,000 or more and 200,000 or less, and particularly preferably 5,000 or more and 100,000 or less.

In addition, from the viewpoint of dielectric loss tangent of the polymer film and adhesiveness with the metal layer, the compound having a functional group is preferably an acrylic resin having a functional group, and more preferably an acrylic copolymer obtained by polymerizing at least a (meth)acrylate compound having a functional group.

In addition, from the viewpoint of surface maldistribution and adhesiveness with the metal layer, the above-described acrylic resin having a functional group is preferably a perfluoroalkyl group having 4 or more carbon atoms, more preferably a perfluoroalkyl group having 4 to 30 carbon atoms, and particularly preferably a perfluoroalkyl group having 5 to 20 carbon atoms.

Furthermore, from the viewpoint of surface maldistribution and adhesiveness with the metal layer, it is preferable that the compound having a functional group contains a silicone atom or a fluorine atom, it is more preferable to be a silicone resin having a functional group or a fluorine-based resin having a functional group, and it is particularly preferable to be a silicone resin having a functional group.

Further, from the viewpoint of dielectric loss tangent of the polymer film and adhesiveness with the metal layer, the compound having a functional group may or may not be a compound compatible with the polymer having a dielectric loss tangent of 0.005 or less or the liquid crystal polymer, but it is preferably a compatible compound. Whether or not the compound having a functional group is compatible with the polymer having a dielectric loss tangent of 0.005 or less or the liquid crystal polymer can be determined based on a difference in SP values.

From the viewpoint of compatibility between the polymer having a dielectric loss tangent of 0.005 or less or the liquid crystal polymer and the compound having a functional group, dielectric loss tangent of the polymer film, and adhesiveness with the metal layer, a difference between an SP value of the polymer having a dielectric loss tangent of 0.005 or less or the liquid crystal polymer, which is determined by Hoy method, and an SP value of the compound having a functional group, which is determined by Hoy method, is preferably 5 MPa^{0.5} or less. The lower limit value of the above-described difference is 0 MPa^{0.5}. In a case where the difference in the SP values is 5 MPa^{0.5} or less, the compound having a functional group and the polymer having a dielectric loss tangent of 0.005 or less or the liquid crystal polymer are in a compatible relationship.

Furthermore, from the viewpoint of surface maldistribution and adhesiveness with the metal layer, the compound having a functional group may be a compound incompatible with the polymer having a dielectric loss tangent of 0.005 or less or the liquid crystal polymer.

From the viewpoint of surface maldistribution and adhesiveness with the metal layer, the difference between the SP value of the polymer having a dielectric loss tangent of 0.005 or less or the liquid crystal polymer, which is determined by Hoy method, and the SP value of the compound having a functional group, which is determined by Hoy method, is preferably more than 5 MPa^{0.5}. The upper limit value of the above-described difference is not particularly limited, but is 50 MPa^{0.5}.

The solubility parameter value (SP value) determined by Hoy method is calculated from the molecular structure by the method described in Polymer Handbook fourth edition. In addition, in a case where the resin is a mixture of a plurality of types of resins, the SP value is obtained by calculating an SP value of each constitutional unit.

[Functional Group]

The functional group in the compound having a functional group is preferably at least one group selected from the group consisting of a covalent-bondable group, an ion-bondable group, a hydrogen-bondable group, and a dipole-interactable group.

From the viewpoint of adhesiveness with the metal layer, the functional group is preferably a covalent-bondable group.

In addition, from the viewpoint of storage stability and handleability, the functional group is preferably an ion-bondable group, a hydrogen-bondable group, or a dipole-interactable group.

-Covalent-Bondable Group-

The covalent-bondable group is not particularly limited as long as the group is capable of forming a covalent bond, and examples thereof include an epoxy group, an oxetanyl group, an isocyanate group, an acid anhydride group, a carbodiimide group, a N-hydroxy ester group, a glyoxal group, an imide ester group, a halogenated alkyl group, a thiol group, a hydroxy group, a carboxy group, an amino group, an amide group, an aldehyde group, and a sulfonic acid group. Among these, from the viewpoint of adhesiveness with the metal layer, the covalent-bondable group is preferably at least one functional group selected from the group consisting of an epoxy group, an oxetanyl group, an isocyanate group, an acid anhydride group, a carbodiimide group, an N-hydroxy ester group, a glyoxal group, an imide ester group, a halogenated alkyl group, and a thiol group, and particularly preferably an epoxy group.

In addition, as will be described later, it is preferable that the surface of the metal to be bonded to the polymer film has a group which is paired with the functional group in the compound having a functional group.

Specific examples of a combination of the covalent-bondable group and a group which can be paired with the covalent-bondable group (a combination of the functional group in the compound having a functional group, which is contained in the polymer film, and the group of the metal) include a combination in which one is an epoxy group and the other is a hydroxy group or an amino group.

In addition, examples of the combination of the covalent-bondable group and the group which can be paired with the covalent-bondable group include a combination in which one is an N-hydroxy ester group or an imide ester group and the other is an amino group.

-Ion-Bondable Group-

Examples of the ion-bondable group include a cationic group and an anionic group.

The above-described cationic group is preferably an onium group. Examples of the onium group include an ammonium group, a pyridinium group, a phosphonium group, an oxonium group, a sulfonium group, a selenonium group, and an iodonium group. Among these, as the ion-bondable group, from the viewpoint of adhesiveness with the metal layer, an ammonium group, a pyridinium group, a phosphonium group, or a sulfonium group is preferable, an ammonium group or a phosphonium group is more preferable, and an ammonium group is particularly preferable.

The anionic group is not particularly limited, and examples thereof include a phenolic hydroxyl group, a carboxy group, —SO₃H, —OSO₃H, —PO₃H, —OPO₃H₂, —CONHSO₂—, and —SO₂NHSO₂—. Among these, as the anionic group, a phosphoric acid group, a phosphonic acid group, a phosphinic acid group, a sulfuric acid group, a sulfonic acid group, a sulfinic acid group, or a carboxy group is preferable, a phosphoric acid group or a carboxy group is more preferable, and a carboxy group is still more preferable.

Specific examples of a combination of the ion-bondable group and a group which can be paired with the ion-bondable group (a combination of the functional group in the compound having a functional group, which is contained in the polymer film, and the group of the metal) include a combination in which one is an acidic group and the other is a basic group.

Examples of the above-described acidic group include a carboxy group, a sulfo group, and a phosphoric acid group, and a carboxy group is preferable.

In addition, examples thereof include an aspect in which, for example, in a case where one is a carboxy group, the ion-bondable group with the carboxy group is a tertiary amino group, a pyridyl group, or a piperidyl group.

-Hydrogen-Bondable Group-

Examples of the hydrogen-bondable group include a group having a hydrogen-bond-donating moiety and a group having a hydrogen-bond-accepting moiety.

It is sufficient that the hydrogen-bond-donating moiety has a structure having an active hydrogen atom capable of hydrogen bonding, and a structure represented by X—H is preferable.

X represents a heteroatom, and is preferably a nitrogen atom or an oxygen atom.

From the viewpoint of adhesiveness with the metal layer, as the above-described hydrogen-bond-donating moiety, at least one structure selected from the group consisting of a hydroxy group, a carboxy group, a primary amide group, a secondary amide group, a primary amino group, a secondary amino group, a primary sulfonamide group, a secondary sulfonamide group, an imide group, a urea bond, and a urethane bond is preferable; at least one structure selected from the group consisting of a hydroxy group, a carboxy group, a primary amide group, a secondary amide group, a primary sulfonamide group, a secondary sulfonamide group, a maleimide group, a urea bond, and a urethane bond is more preferable; at least one structure selected from the group consisting of a hydroxy group, a carboxy group, a primary amide group, a secondary amide group, a primary sulfonamide group, a secondary sulfonamide group, and a maleimide group is still more preferable; and at least one structure selected from the group consisting of a hydroxy group and a secondary amide group is particularly preferable.

As the above-described hydrogen-bond-accepting moiety, a structure containing an atom with an unshared electron pair is preferable; a structure containing an oxygen atom with an unshared electron pair is more preferable; at least one structure selected from the group consisting of a carbonyl group (including a carbonyl structure such as a carboxy group, an amide group, an imide group, a urea bond, and a urethane bond) and a sulfonyl group (including a sulfonyl structure such as a sulfonamide group) is still more preferable; and a carbonyl group (including a carbonyl structure such as a carboxy group, an amide group, an imide group, a urea bond, and a urethane bond) is particularly preferable.

As the hydrogen-bondable group, a group having both the hydrogen-bond-donating moiety and the hydrogen-bond-accepting moiety described above is preferable; it is preferable to have a carboxy group, an amide group, an imide group, a urea bond, a urethane bond, or a sulfonamide group, and it is more preferable to have a carboxy group, an amide group, an imide group, or a sulfonamide group.

Specific examples of a combination of the hydrogen-bondable group and a group which can be paired with the hydrogen-bondable group (a combination of the functional group in the compound having a functional group and the group present in the surface of the metal) include a combination in which one is a group having a hydrogen-bond-donating moiety and the other is a group having a hydrogen-bond-accepting moiety.

Examples thereof include an aspect in which, in a case where one is a carboxy group, the other is an amide group or a carboxy group.

In addition, examples of the combination of the hydrogen-bondable group and the group which can be paired with the hydrogen-bondable group include a combination in which one is a phenolic hydroxyl group and the other is a phenolic hydroxyl group.

-Dipole-Interactable Group-

It is sufficient that the dipole-interactable group is a group having a polarized structure other than the above-described structure represented by X—H (X represents a heteroatom) in the hydrogen-bondable group, and suitable examples thereof include a group in which atoms with different electronegativities are bonded to each other.

As a combination of the atoms with different electronegativities, a combination of at least one atom selected from the group consisting of an oxygen atom, a nitrogen atom, a sulfur atom, and a halogen atom, and a carbon atom is preferable; and a combination of at least one atom selected from the group consisting of an oxygen atom, a nitrogen atom, and a sulfur atom, and a carbon atom is more preferable.

Among these, from the viewpoint of adhesiveness with the metal layer, a combination of a nitrogen atom and a carbon atom or a combination of a carbon atom, a nitrogen atom, an oxygen atom, and a sulfur atom is preferable, and specifically, a cyano group, a cyanuric group, or a sulfonic acid amide group is more preferable.

Preferred examples of a combination of the dipole-interactable group and a group which can be paired with the dipole-interactable group (a combination of the functional group in the compound having a functional group and the group present in the surface of the metal) include a combination of identical dipole-interactable groups.

Examples of the combination of the dipole-interactable group and the group which can be paired with the dipole-interactable group include a combination in which one is a cyano group and the other is a cyano group.

In addition, examples of the combination of the dipole-interactable group and the group which can be paired with the dipole-interactable group include a combination in which one is a sulfonic acid amide group and the other is a sulfonic acid amide group.

As the functional group in the compound having a functional group, specifically, it is preferable to have an epoxy group, an oxetanyl group, an isocyanate group, an acid anhydride group, a carbodiimide group, an N-hydroxy ester group, a glyoxal group, an imidoester group, a halogenated alkyl group, a thiol group, a hydroxy group, a carboxy group, an amino group, an amide group, an isocyanate group, an aldehyde group, a sulfuric acid group, a sulfonic acid group, an ammonium group, a pyridinium group, a phosphonium group, an oxonium group, a sulfonium group, a selenonium group, an iodonium group, a phosphoric acid group, a phosphonic acid group, a phosphinic acid group, a sulfonic acid group, or at least one selected from the group consisting of a sulfinic acid group or a carboxy group, a hydroxy group, a carboxy group, a primary amide group, a secondary amide group, a primary amino group, a secondary amino group, a primary sulfonamide group, a secondary sulfonamide group, an imide group, a urea bond, and a urethane bond. From the viewpoint of improving the adhesiveness, as the functional group in the compound having a functional group, an epoxy group, an oxetanyl group, an isocyanate group, an acid anhydride group, a carbodiimide group, an N-hydroxy ester group, a glyoxal group, an imidoester group, a halogenated alkyl group, or a thiol group is more preferable.

Specific examples of the bonds or interaction between two kinds of the functional groups are described below, but the bonds or interaction in the present disclosure is not limited thereto.

### Covalent Bond

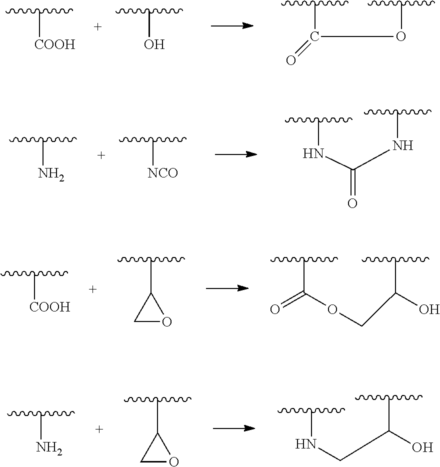

### Ion Bond

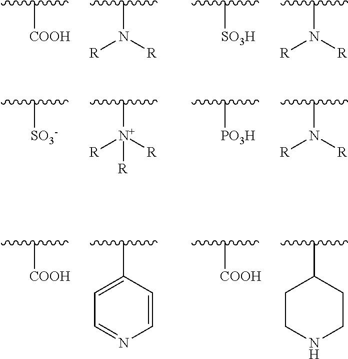

### Hydrogen Bond

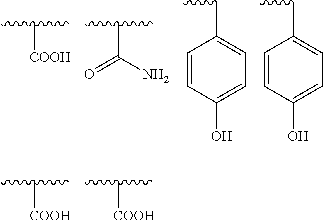

### Dipole Interaction

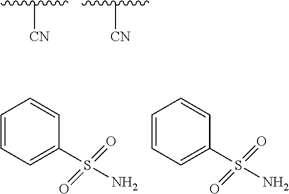

From the viewpoint of dielectric loss tangent of the polymer film and adhesiveness with the metal layer, the compound having a functional group is preferably a polymer having a functional group, and more preferably an acrylic resin having a functional group or a silicone resin having a functional group.

In addition, from the viewpoint of dielectric loss tangent of the polymer film and adhesiveness with the metal layer, the compound having a functional group preferably includes a liquid crystal polymer obtained by polymerizing a liquid crystal polymer precursor having a polymerizable group.

The polymer film may contain only one or two or more kinds of the compounds having a functional group.

From the viewpoint of dielectric loss tangent of the polymer film and adhesiveness with the metal layer, the content of the compound having a functional group in the polymer film is preferably 0.05% by mass to 50% by mass, more preferably 0.1% by mass to 30% by mass, still more preferably 0.2% by mass to 10% by mass, and particularly preferably 0.5% by mass to 5% by mass with respect to the total mass of the polymer film.

<Third Component and Immobilization>

From the viewpoint of dielectric loss tangent of the polymer film, adhesiveness with the metal layer, heat resistance, and mechanical strength, it is preferable that the polymer film according to the embodiment of the present disclosure further contains a third component in which the above-described compound having a functional group is immobilized to the above-described polymer having a dielectric loss tangent of 0.005 or less or the above-described liquid crystal polymer.

In addition, the third component is preferably a compound other than the above-described polymer having a dielectric loss tangent of 0.005 or less or the above-described liquid crystal polymer, and the above-described compound having a functional group.

Preferred examples of a method for immobilizing the above-described compound having a functional group to the above-described polymer having a dielectric loss tangent of 0.005 or less or the above-described liquid crystal polymer include a method of forming a three-dimensional crosslinking structure in the polymer film for the immobilization, and a method of immobilizing using an entanglement of polymers with a polymer which has a functional group interacting with the above-described compound having a functional group and is compatible with the above-described polymer having a dielectric loss tangent of 0.005 or less or the above-described liquid crystal polymer.

From the viewpoint of dielectric loss tangent of the polymer film, adhesiveness with the metal layer, heat resistance, and mechanical strength, the polymer film according to the embodiment of the present disclosure preferably has a three-dimensional crosslinking structure.

Examples of the method of forming the three-dimensional crosslinking structure include a method of polymerizing a polyfunctional reactive compound (for example, a polyfunctional monomer) to form a cured substance of the polyfunctional reactive compound.

That is, from the viewpoint of dielectric loss tangent of the polymer film, adhesiveness with the metal layer, heat resistance, and mechanical strength, the third component preferably includes a cured substance of a polyfunctional reactive compound, and more preferably includes a cured substance of a polyfunctional (meth)acrylate compound.

Here, the cured substance of a polyfunctional reactive compound means a compound in which a reactive group in the polyfunctional reactive compound has substantially lost its reactivity due to various curing reactions such as a crosslinking reaction and a polymerization reaction. That is, a part of the reactive groups in the polyfunctional reactive compound may be unreactive, and for example, it is sufficient that 50% or more of all reactive groups in the polyfunctional reactive compound disappears. A proportion of the disappearance of the reactive group in the polyfunctional reactive compound is preferably 80% or more, more preferably 90% or more, and still more preferably 100% (that is, in a state in which all reactive groups in the polyfunctional reactive compound disappear). The degree of disappearance of the reactive group can be measured by a known method, and examples thereof include a method of identifying the cured substance of a polyfunctional reactive compound, contained in the polymer film, and measuring the cured substance by infrared absorption spectrum and the like.

The cured substance of a polyfunctional reactive compound may be a homopolymer of the polyfunctional reactive compound, a copolymer of two or more polyfunctional reactive compounds, or a copolymer of one or more polyfunctional reactive compounds and one or more monofunctional reactive compounds (monofunctional monomers).

The cured substance of a polyfunctional reactive compound is not particularly limited, but is preferably an addition polymerization resin.

As the polyfunctional reactive compound, a known polyfunctional monomer can be used, and a polyfunctional ethylenically unsaturated compound is preferable.

Examples of the polyfunctional ethylenically unsaturated compound include a polyfunctional (meth)acrylate compound, a polyfunctional (meth)acrylamide compound, a polyfunctional vinyl compound, a polyfunctional styrene compound, and a mixture thereof. Among these, the polyfunctional ethylenically unsaturated compound is preferably a polyfunctional (meth)acrylate compound.

In addition, in the cured substance of the polyfunctional reactive compound, a monofunctional reactive compound may be copolymerized in order to adjust a mesh size of the three-dimensional crosslinking structure.

In addition, it is preferable to use a polymerization initiator for forming the cured substance of a polyfunctional reactive compound. As the polymerization initiator, a known photopolymerization initiator, a known thermal polymerization initiator, or the like can be used. Among these, the polymerization initiator is preferably a photopolymerization initiator.

In addition, in the polymer film according to the embodiment of the present disclosure, from the viewpoint of dielectric loss tangent of the polymer film, adhesiveness with the metal layer, heat resistance, and mechanical strength, the polyfunctional reactive compound preferably includes a liquid crystal polymer precursor.

The precursor of a liquid crystal polymer is not particularly limited as long as it is a polymerizable liquid crystal polymer. The precursor of a liquid crystal polymer may be one in which a polymerizable group is generated by a predetermined treatment (for example, an annealing treatment and a surface treatment such as plasma) during manufacturing the polymer film, or a liquid crystal polymer precursor itself may have a polymerizable group.

In the polymer film according to the embodiment of the present disclosure, from the viewpoint of dielectric loss tangent of the polymer film, adhesiveness with the metal layer, heat resistance, and mechanical strength, the third component preferably includes the compound which has a functional group interacting with the above-described compound having a functional group and is compatible with the polymer having a dielectric loss tangent of 0.005 or less or the liquid crystal polymer, more preferably includes a polymer which has a functional group interacting with the above-described compound having a functional group and is compatible with the polymer having a dielectric loss tangent of 0.005 or less or the liquid crystal polymer, and particularly preferably includes a liquid crystal polymer which has a functional group interacting with the above-described compound having a functional group and is compatible with the polymer having a dielectric loss tangent of 0.005 or less or the liquid crystal polymer.

Preferred aspects of the functional group in the compound which has a functional group interacting with the above-described compound having a functional group and is compatible with the polymer having a dielectric loss tangent of 0.005 or less or the liquid crystal polymer are the same as the functional group in the above-described compound having a functional group, except that it is a functional group paired with the functional group in the above-described compound having a functional group. For example, in a case where the functional group in the above-described compound having a functional group is an epoxy group, preferred examples of the functional group in the third component include an amino group and a hydroxy group.

From the viewpoint of compatibility, dielectric loss tangent of the polymer film, and adhesiveness with the metal layer, a difference between an SP value of the polymer having a dielectric loss tangent of 0.005 or less or the liquid crystal polymer, which is determined by Hoy method, and an SP value of the compound which has a functional group interacting with the above-described compound having a functional group and is compatible with the polymer having a dielectric loss tangent of 0.005 or less or the liquid crystal polymer, the SP value being determined by Hoy method, is preferably 5 MPa^{0.5} or less. The lower limit value of the above-described difference is 0 MPa^{0.5}.

The method for measuring the SP value by the Hoy method is as described above.

Whether or not the third component is compatible with the polymer having a dielectric loss tangent of 0.005 or less can be determined based on a difference in SP values. In a case where the difference in the SP values is 5 MPa^{0.5} or less, the third component and the polymer having a dielectric loss tangent of 0.005 or less are in a compatible relationship.

The polymer film may contain only one or two or more kinds of the third components.

From the viewpoint of dielectric loss tangent of the polymer film and adhesiveness with the metal layer, the content of the third component in the polymer film is preferably 1% by mass to 80% by mass, more preferably 2% by mass to 70% by mass, still more preferably 3% by mass to 60% by mass, and particularly preferably 5% by mass to 55% by mass with respect to the total mass of the polymer film.

<Filler>

From the viewpoint of linear expansion coefficient and adhesiveness with the metal layer, the polymer film preferably contains a filler.

The filler may be particulate or fibrous, and may be an inorganic filler or an organic filler.

In the polymer film according to the embodiment of the present disclosure, from the viewpoint of linear expansion coefficient and adhesiveness with the metal layer, it is preferable that a number density of the above-described filler is higher inside the above-described polymer film than on the surface of the above-described polymer film.

The number density of the filler is measured by the following method.

The film is cut with a microtome to produce a cross-sectional sample. The cross-sectional sample is observed with a scanning electron microscope (approximately 100 times to 300 times). Three or more sites are observed so that the total observation area is 0.5 mm² or more, and the number of fillers per 1 mm² is obtained as an average value.

As the inorganic filler, a known inorganic filler can be used.

Examples of a material of the inorganic filler include BN, Al₂O₃, AlN, TiO₂, SiO₂, barium titanate, strontium titanate, aluminum hydroxide, calcium carbonate, and a material containing two or more of these.

Among these, as the inorganic filler, from the viewpoint of adhesiveness with the metal layer, metal oxide particles or fibers are preferable, silica particles, titania particles, or glass fibers are more preferable, and silica particles or glass fibers are particularly preferable.

An average particle diameter of the inorganic filler is preferably approximately 20% to approximately 40% of the thickness of the layer A, and for example, the average particle diameter may be selected from 25%, 30%, or 35% of the thickness of the layer A. In a case where the particles or fibers are flat, the average particle diameter indicates a length in a short side direction.

In addition, from the viewpoint of adhesiveness with the metal layer, the average particle diameter of the inorganic filler is preferably 5 nm to 20 μm, more preferably 10 nm to 10 μm, still more preferably 20 nm to 1 μm, and particularly preferably 25 nm to 500 nm.

As the organic filler, a known organic filler can be used.

Examples of a material of the organic filler include polyethylene, polystyrene, urea resin, polyester, cellulose, acrylic resin, fluororesin, cured epoxy resin, crosslinked benzoguanamine resin, crosslinked acrylic resin, a liquid crystal polymer, and a material containing two or more kinds of these.

In addition, the organic filler may be fibrous, such as nanofibers, or may be hollow resin particles.

Among these, as the organic filler, from the viewpoint of thermal expansion coefficient and adhesiveness with the metal layer, fluororesin particles, polyester-based resin particles, polyethylene particles, liquid crystal polymer particles, or cellulose-based resin nanofibers are preferable, and polytetrafluoroethylene particles, polyethylene particles, or liquid crystal polymer particles are more preferable.

Here, the liquid crystal polymer particles can be produced, for example, by polymerizing the liquid crystal polymer and crushing the liquid crystal polymer with a crusher or the like to form a powder. The average particle diameter of the liquid crystal polymer particles is preferably smaller than the thickness of each layer.

From the viewpoint of thermal expansion coefficient and adhesiveness with the metal layer, an average particle diameter of the organic filler is preferably 5 nm to 20 μm, more preferably 10 nm to 1 μm, still more preferably 20 nm to 500 nm, and particularly preferably 25 nm to 90 nm.

The polymer film may contain only one or two or more kinds of the fillers.

From the viewpoint of adhesiveness with the metal layer, the content of the filler in the polymer film is preferably 5% by volume to 80% by volume, more preferably 10% by volume to 70% by volume, still more preferably 15% by volume to 70% by volume, and particularly preferably 20% by volume to 60% by volume with respect to the total volume of the polymer film.

-Other Additives-

The polymer film may contain an additive other than the above-described components.

Known additives can be used as other additives. Specific examples of the other additives include a leveling agent, an antifoaming agent, an antioxidant, an ultraviolet absorbing agent, a flame retardant, and a colorant.

In addition, the polymer film may contain, as the other additives, a resin other than the polymer having a dielectric loss tangent of 0.005 or less or the liquid crystal polymer, and the compound having a functional group.

Examples of other resins include thermoplastic resins such as polypropylene, polyamide, polyester, polyphenylene sulfide, polyether ketone, polycarbonate, polyethersulfone, polyphenylene ether and a modified product thereof, and polyetherimide; elastomers such as a copolymer of glycidyl methacrylate and polyethylene; and thermosetting resins such as a phenol resin, an epoxy resin, a polyimide resin, and a cyanate resin.

The total content of the other additives in the polymer film is preferably 25 parts by mass or less, more preferably 10 parts by mass or less, and still more preferably 5 parts by mass or less with respect to 100 parts by mass of the content of the polymer having a dielectric loss tangent of 0.005 or less.

In addition, it is preferable that the total content of the other additives in the polymer film is smaller than the content of the compound having a functional group.

In addition, the polymer film according to the embodiment of the present disclosure may have a multilayer structure.

It is preferable that the polymer film according to the embodiment of the present disclosure includes a layer A and a layer B on at least one surface of the layer A, and the layer B contains the above-described compound having a functional group.

From the viewpoint of dielectric loss tangent of the polymer film and adhesiveness with the metal layer, it is preferable that the polymer film according to the embodiment of the present disclosure includes a layer A containing the polymer having a dielectric loss tangent of 0.005 or less or the liquid crystal polymer and a layer B containing the polymer having a dielectric loss tangent of 0.005 or less or the liquid crystal polymer, and the compound having a functional group, the layer B being on at least one surface of the layer A; and from the viewpoint of dielectric loss tangent of the polymer film and adhesiveness with the metal layer, it is more preferable that the polymer film according to the embodiment of the present disclosure includes a layer A containing the polymer having a dielectric loss tangent of 0.005 or less or the liquid crystal polymer and a layer B containing the polymer having a dielectric loss tangent of 0.005 or less or the liquid crystal polymer, the compound having a functional group, and the third component, the layer B being on at least one surface of the layer A.

The layer A may contain only the polymer having a dielectric loss tangent of 0.005 or less or the liquid crystal polymer, or may contain the polymer having a dielectric loss tangent of 0.005 or less or the liquid crystal polymer, and the compound having a functional group.

In addition, the layer A may further contain the third component, but it is preferable to not contain the third component.

Furthermore, it is preferable that the layer A further contains the filler.

It is preferable that the layer B contains the polymer having a dielectric loss tangent of 0.005 or less or the liquid crystal polymer, and the compound having a functional group, and it is more preferable that the layer B contains the polymer having a dielectric loss tangent of 0.005 or less or the liquid crystal polymer, the compound having a functional group, and the third component in which the compound having a functional group is immobilized to the polymer having a dielectric loss tangent of 0.005 or less.

In addition, from the viewpoint of dielectric loss tangent of the polymer film and adhesiveness with the metal layer, it is preferable that a content of the third component in the layer B is larger than a content of the third component in the layer A.

In addition, it is preferable that the polymer film according to the embodiment of the present disclosure further includes a layer C in addition to the layer A and the layer B, and the layer B, the layer A, and the layer C are provided in this order.

In a case where a metal layer is present separately from each of the above-described layers, the layer C is preferably a surface layer (outermost layer), and more preferably a surface layer on a side to which the metal is attached.

In addition, in a case where the film according to the embodiment of the present disclosure is used as a laminate having a metal layer (for example, a metal foil or a metal wire), it is preferable that the layer C is disposed between the metal layer and the layer A.

It is preferable that the layer C contains the polymer having a dielectric loss tangent of 0.005 or less or the liquid crystal polymer, and the compound having a functional group; and it is more preferable that the layer C contains the polymer having a dielectric loss tangent of 0.005 or less or the liquid crystal polymer, the compound having a functional group, and the third component in which the compound having a functional group is immobilized to the polymer having a dielectric loss tangent of 0.005 or less or the liquid crystal polymer.

In addition, from the viewpoint of dielectric loss tangent of the polymer film and adhesiveness with the metal layer, it is preferable that a content of the third component in the layer C is larger than the content of the third component in the layer A.

The average thickness of the layer A is not particularly limited, but from the viewpoint of dielectric loss tangent of the polymer film and adhesiveness with the metal layer, the average thickness thereof is preferably 5 μm to 90 μm, more preferably 10 μm to 70 μm, and particularly preferably 15 μm to 50 μm.

A method for measuring the average thickness of each layer in the polymer film according to the embodiment of the present disclosure is as follows.

The thickness of each layer is evaluated by cutting the polymer film with a microtome and observing the cross section with an optical microscope. Three or more sites of the cross-sectional sample are cut out, the thickness is measured at three or more points in each cross section, and the average value thereof is defined as the average thickness.

From the viewpoint of dielectric loss tangent of the polymer film and adhesiveness with the metal layer, it is preferable that average thicknesses of the layer B and the layer C are each independently smaller than the average thickness of the layer A.

From the viewpoint of dielectric loss tangent of the polymer film and adhesiveness with the metal layer, a value of T^{A}/T^{B}, which is a ratio of an average thickness T^{A} of the layer A to an average thickness T^{B} of the layer B, is preferably more than 1, more preferably 2 to 100, still more preferably 2.5 to 20, and particularly preferably 3 to 10.

From the viewpoint of dielectric loss tangent of the polymer film and adhesiveness with the metal layer, a value of T^{A}/T^{C}, which is a ratio of the average thickness T^{A} of the layer A to an average thickness T^{C} of the layer C, is preferably more than 1, more preferably 2 to 100, still more preferably 2.5 to 20, and particularly preferably 3 to 10.

In addition, from the viewpoint of linear expansion coefficient and adhesiveness with the metal layer, a value of T^{C}/T^{B}, which is a ratio of the average thickness T^{C} of the layer C to the average thickness T^{B} of the layer B, is preferably 0.2 to 5, more preferably 0.5 to 2, and particularly preferably 0.8 to 1.2.

Furthermore, from the viewpoint of dielectric loss tangent of the polymer film and adhesiveness with the metal layer, the average thicknesses of the layer B and the layer C are each independently preferably 0.1 μm to 20 μm, more preferably 0.5 μm to 15 μm, still more preferably 1 μm to 10 μm, and particularly preferably 3 μm to 8 μm.

From the viewpoint of strength, dielectric loss tangent of the polymer film, and adhesiveness with the metal layer, an average thickness of the polymer film according to the embodiment of the present disclosure is preferably 6 μm to 200 μm, more preferably 12 μm to 100 μm, and particularly preferably 20 μm to 60 μm.

The average thickness of the polymer film is measured at any five places using an adhesive film thickness meter. The measurement is performed, for example, using an electronic micrometer (product name “KG3001A”, manufactured by Anritsu Corporation) as a film thickness meter, and an average value of the measured values is employed.

From the viewpoint of dielectric constant, the dielectric loss tangent of the polymer film according to the embodiment of the present disclosure is preferably 0.020 or less, more preferably 0.010 or less, still more preferably 0.005 or less, and particularly preferably more than 0 and 0.003 or less. The dielectric loss tangent is measured by the same method as in the dielectric loss tangent described above.

A linear expansion coefficient of the polymer film according to the embodiment of the present disclosure is preferably −20 ppm/K to 50 ppm/K, more preferably −10 ppm/K to 40 ppm/K, still more preferably 0 ppm/K to 35 ppm/K, and particularly preferably 10 ppm/K to 30 ppm/K.

The linear expansion coefficient in the present disclosure is measured by the following method.

Using a thermomechanical analyzer (TMA), a tensile load of 1 g is applied to both ends of a measurement sample of the polymer film or each layer, which has a width of 5 mm and a length of 20 mm, and the measurement sample is heated from 25° C. to 200° C. at a rate of 5° C/min. Thereafter, the measurement sample was cooled to 30° C. at a rate of 20° C./min and then heated again at a rate of 5° C./min, and the linear expansion coefficient is calculated from the inclination of TMA curve between 30° C. to 150° C.

In a case where each layer is measured, a measurement sample may be produced by scraping off the layer to be measured with a razor or the like.

In addition, in a case where it is difficult to measure the linear expansion coefficient by the above-described method, the measurement is carried out by the following method.

The film is cut with a microtome to produce a section sample, and the section sample is set in an optical microscope equipped with a heating stage system (HS82, manufactured by METTLER TOLEDO). Subsequently, the section sample is heated from 25° C. to 200° C. at a rate of 5° C./min. Thereafter, the section sample is cooled to 30° C. at a rate of 20° C./min and then heated again at a rate of 5° C./min, and a thickness of the polymer film or each layer at 30° C. (ts30) and a thickness of the polymer film or each layer at 150° C. (ts150) are evaluated. Thereafter, a value obtained by dividing the dimensional change by the temperature change ((ts150−ts30)/(150−30)) is calculated to obtain the linear expansion coefficient of the polymer film or each layer.

<Method of Manufacturing Polymer Film>

[Film Formation]

A method of manufacturing the polymer film according to the embodiment of the present disclosure is not particularly limited, and a known method can be referred to.

Suitable examples of the method of manufacturing the polymer film according to the embodiment of the present disclosure include a casting method, a coating method, and an extrusion method, and among these, a casting method is particularly preferable. In addition, in a case where the polymer film according to the embodiment of the present disclosure has a multilayer structure, suitable examples thereof include a co-casting method, a multilayer coating method, and a co-extrusion method. Among these, the co-casting method is particularly preferable for formation of a relatively thin film, and the co-extrusion method is particularly preferable for formation of a thick film.

In a case where the multilayer structure in the polymer film is manufactured by the co-casting method or the multilayer coating method, it is preferable that the co-casting method or the multilayer coating method is performed by using a composition for forming the layer A, a composition for forming the layer B, a composition for forming the layer C, or the like obtained by dissolving or dispersing components of each layer, such as the liquid crystal polymer, in a solvent.

Examples of the solvent include halogenated hydrocarbons such as dichloromethane, chloroform, 1,1-dichloroethane, 1,2-dichloroethane, 1,1,2,2-tetrachloroethane, 1-chlorobutane, chlorobenzene, and o-dichlorobenzene; halogenated phenols such as p-chlorophenol, pentachlorophenol, and pentafluorophenol; ethers such as diethyl ether, tetrahydrofuran, and 1,4-dioxane; ketones such as acetone and cyclohexanone; esters such as ethyl acetate and γ-butyrolactone; carbonates such as ethylene carbonate and propylene carbonate; amines such as triethylamine; nitrogen-containing heterocyclic aromatic compounds such as pyridine; nitriles such as acetonitrile and succinonitrile; amides such as N,N-dimethylformamide, N,N-dimethylacetamide, and N-methylpyrrolidone; urea compounds such as tetramethylurea; nitro compounds such as nitromethane and nitrobenzene; sulfur compounds such as dimethyl sulfoxide and sulfolane; and phosphorus compounds such as hexamethylphosphoramide and tri-n-butyl phosphate. Among these, two or more kinds thereof may be used in combination.

The solvent preferably contains an aprotic compound, particularly, an aprotic compound having no halogen atom for low corrosiveness and easiness to handle. A proportion of the aprotic compound to the whole solvent is preferably 50% by mass to 100% by mass, more preferably 70% by mass to 100% by mass, and particularly preferably 90% by mass to 100% by mass. In addition, from the viewpoint of easily dissolving the liquid crystal polymer, as the above-described aprotic compound, an amide such as N,N-dimethylformamide, N,N-dimethylacetamide, tetramethylurea, and N-methylpyrrolidone, or an ester such as γ-butyrolactone is preferable; and N,N-dimethylformamide, N,N-dimethylacetamide, or N-methylpyrrolidone is more preferable.

In addition, as the solvent, it is preferable to contain a compound having a dipole moment of 3 to 5, because the liquid crystal polymer can be easily dissolved. A proportion of the compound having a dipole moment of 3 to 5 to the whole solvent is preferably 50% by mass to 100% by mass, more preferably 70% by mass to 100% by mass, and particularly preferably 90% by mass to 100% by mass.

It is preferable to use the compound having a dipole moment of 3 to 5 as the above-described aprotic compound.

In addition, as the solvent, it is preferable to contain a compound having a boiling point of 220° C. or lower at 1 atm, because the solvent is easily removed. A proportion of the compound having a boiling point of 220° C. or lower at 1 atm to the whole solvent is preferably 50% by mass to 100% by mass, more preferably 70% by mass to 100% by mass, and particularly preferably 90% by mass to 100% by mass.

It is preferable to use the compound having a boiling point of 220° C. or lower at 1 atm as the above-described aprotic compound.

In addition, in a case where the polymer film is manufactured by the casting method, co-casting method, coating method, multilayer coating method, extrusion method, co-extrusion method, or the like described above, a support may be used in the method of manufacturing the polymer film according to the embodiment of the present disclosure. In addition, in a case where the metal layer (metal foil) or the like used in the laminate described later is used as the support, the support may be used as it is without being peeled off.

Examples of the support include a metal drum, a metal band, a glass plate, a resin film, and a metal foil. Among these, the support is preferably a metal drum, a metal band, or a resin film.

Examples of the resin film include a polyimide (PI) film. Examples of commercially available products of the resin film include U-PILEX S and U-PILEX R (manufactured by Ube Corporation), KAPTON (manufactured by Du Pont-Toray Co., Ltd.), and IF30, IF70, and LV300 (manufactured by SKC Kolon PI, Inc.).

In addition, the support may have a surface treatment layer formed on the surface so that the support can be easily peeled off. Hard chrome plating, a fluororesin, or the like can be used as the surface treatment layer.

An average thickness of the support is not particularly limited, but is preferably 25 μm or more and 75 μm or less and more preferably 50 μm or more and 75 μm or less.

In addition, a method for removing at least a part of the solvent from a cast or applied film-like composition (a casting film or a coating film) is not particularly limited, and a known drying method can be used.

[Stretching]

In the polymer film according to the embodiment of the present disclosure, stretching can be combined as appropriate from the viewpoint of controlling molecular alignment and adjusting thermal expansion coefficient and mechanical properties. The stretching method is not particularly limited, and a known method can be referred to, and the stretching method may be carried out in a solvent-containing state or in a dry film state. The stretching in the solvent-containing state may be carried out by gripping and stretching the film, or may be carried out by utilizing self-contraction due to drying without stretching. The stretching is particularly effective for the purpose of improving the breaking elongation and the breaking strength, in a case where brittleness of the film is reduced by addition of an inorganic filler or the like.

In addition, the method of manufacturing the polymer film according to the embodiment of the present disclosure may optionally include a step of polymerizing with light or heat.

A light irradiation unit and a heat application unit are not particularly limited, and a known light irradiation unit such as a metal halide lamp and a known heat application unit such as a heater can be used.

Light irradiation conditions and heat application conditions are not particularly limited, and the polymerization can be carried out at a desired temperature and time and in a known atmosphere.

[Heat Treatment]

The method of manufacturing the polymer film according to the embodiment of the present disclosure preferably includes a step of heat-treating (annealing) the film after the film formation.

Specifically, from the viewpoint of dielectric loss tangent and peel strength, the heat treatment temperature in the above-described step of heat-treating is preferably 260° C. to 370° C., more preferably 280° C. to 360° C., and still more preferably 300° C. to 350° C. The heat treatment time is preferably 15 minutes to 10 hours and more preferably 30 minutes to 5 hours.

In addition, the method of manufacturing the polymer film according to the embodiment of the present disclosure may include other known steps as necessary.

<Applications>

The polymer film according to the embodiment of the present disclosure can be used for various applications. Among the various applications, the polymer film can be used suitably as a film for an electronic component such as a printed wiring board and more suitably for a flexible printed circuit board.

In addition, the polymer film according to the embodiment of the present disclosure can be suitably used as a polymer film for metal adhesion.

(Laminate)

The laminate according to the embodiment of the present disclosure may be one in which the polymer film according to the embodiment of the present disclosure is laminated, but it is preferable to include the polymer film according to the embodiment of the present disclosure and a metal layer disposed on a surface in which a concentration of the above-described compound having a functional group in the polymer film is higher than inside of the polymer film; it is more preferable to include the polymer film according to the embodiment of the present disclosure and metal layers respectively disposed on both surfaces of the polymer film; and it is particularly preferable to include metal layers respectively disposed on both surfaces of the polymer film, in which a concentration of the above-described compound having a functional group in the polymer film is higher than inside of the polymer film.

The metal layer may be a known metal layer, but is, for example, preferably a copper layer. That is, the laminate according to the embodiment of the present disclosure preferably includes the polymer film according to the embodiment of the present disclosure and a metal layer in which a concentration of the above-described compound having a functional group in the polymer film is higher than inside of the polymer film, and more preferably includes the polymer film according to the embodiment of the present disclosure and the metal layers respectively disposed on both surfaces of the polymer film.

In addition, in the laminate according to the embodiment of the present disclosure, from the viewpoint of adhesiveness with the metal layer, it is preferable that the polymer film according to the embodiment of the present disclosure includes the layer A and the layer B on at least one surface of the layer A, the above-described metal layer (preferably, the copper layer) is disposed on the layer B, and the thickness of the layer B is larger than the thickness of the above-described metal layer (preferably, the copper layer) disposed on the layer B.

The metal layer disposed on the surface of the above-described layer B side is preferably a metal layer disposed on the surface of the above-described layer B.

Furthermore, it is preferable that the laminate according to the embodiment of the present disclosure includes the polymer film according to the embodiment of the present disclosure in which the layer B, the layer A, and the layer C are provided in this order, a metal layer disposed on a surface of the above-described layer B side of the polymer film, and a metal layer disposed on a surface of the above-described layer C side of the polymer film; and it is more preferable that both of the metal layers are copper layers.

It is preferable that the metal layer disposed on the surface of the above-described layer C side is a metal layer disposed on the surface of the above-described layer C, and it is more preferable that the metal layer disposed on the surface of the above-described layer B side is a metal layer disposed on the surface of the above-described layer B, and the metal layer disposed on the surface of the above-described layer C side is a metal layer disposed on the surface of the above-described layer C.

The metal layer disposed on the surface of the above-described layer B side and the metal layer disposed on the surface of the above-described layer C side may be a metal layer having the same material, thickness, and shape, or may be metal layers having different materials, thicknesses, and shapes. From the viewpoint of adjusting the characteristic impedance, it is preferable that the metal layer disposed on the surface of the above-described layer B side and the metal layer disposed on the surface of the above-described layer C side are metal layers having different materials.

Further, from the viewpoint of adjusting the characteristic impedance, an aspect in which a metal layer is laminated on the metal layer side disposed on a surface of the layer B or the layer C, in which the concentration of the above-described compound having a functional group in the polymer film is higher than inside of the polymer film, and another polymer film (preferably, another liquid crystal polymer film) is laminated on the other metal layer side may be used.

In a case of not including the layer C, a surface roughness Rz of the above-described metal layer on the side in contact with the above-described polymer film is preferably 1 μm to 10 μm, more preferably 1 μm to 5 μm, and particularly preferably 1.5 μm to 3 μm. In addition, in a case of including the layer C, from the viewpoint of reducing transmission loss of high-frequency signal, the surface roughness Rz thereof is preferably less than 1 μm, more preferably 0.5 μm or less, and particularly preferably 0.3 μm or less.

Since it is preferable that the surface roughness Rz of the above-described metal layer is as small as possible, the lower limit value thereof is not particularly limited, but is, for example, 0 μm.

The “surface roughness Rz” in the present disclosure refers to a value expressed in micrometer, which is the total value of the maximum value of height of peak and the maximum value of depth of valley observed on a roughness curve over the reference length.

In the present disclosure, the surface roughness Rz of the metal layer (for example, the copper layer) is measured by the following method.

Using a noncontact surface/layer cross-sectional shape measurement system VertScan (manufactured by MITSUBISHI CHEMICAL SYSTEMS, Inc.), a square of 465.48 μm in length and 620.64 μm in width is measured to create a roughness curve on the surface of the measurement object (metal layer) and create an average line of the roughness curve. A portion corresponding to the reference length is extracted from the roughness curve. The surface roughness Rz of the measurement object is measured by obtaining the total value of the maximum value of height of peak (that is, height from the average line to summit) and the maximum value of depth of valley (that is, height from the average line to valley bottom) observed in the extracted roughness curve.

A method of attaching the polymer film according to the embodiment of the present disclosure to the metal layer is not particularly limited, and a known laminating method can be used.

A peel strength between the above-described polymer film and the above-described copper layer is preferably 0.5 kN/m or more, more preferably 0.7 kN/m or more, still more preferably 0.7 kN/m to 2.0 kN/m, and particularly preferably 0.9 kN/m to 1.5 kN/m.

In the present disclosure, the peel strength between the polymer film and the metal layer (for example, the copper layer) is measured by the following method.

A peeling test piece with a width of 1.0 cm is produced from the laminate of the polymer film and the metal layer, the polymer film is fixed to a flat plate with double-sided adhesive tape, and the strength (kN/m) in a case of peeling the metal layer off from the polymer film at a rate of 50 mm/min is measured by the 180° method in conformity with JIS C 5016 (1994).

The metal layer is preferably a copper layer. As the copper layer, a rolled copper foil formed by a rolling method or an electrolytic copper foil formed by an electrolytic method is preferable, and a rolled copper foil is more preferable from the viewpoint of bending resistance.

An average thickness of the metal layer, preferably the copper layer, is not particularly limited, but is preferably 2 μm to 20 μm, more preferably 3 μm to 18 μm, and still more preferably 5 μm to 12 μm. The copper foil may be copper foil with a carrier formed on a support (carrier) so as to be peelable. As the carrier, a known carrier can be used. An average thickness of the carrier is not particularly limited, but is preferably 10 μm to 100 μm and more preferably 18 μm to 50 μm.

In addition, from the viewpoint of further exhibiting the effects of the present disclosure, it is preferable that the above-described metal layer contains a group capable of interacting with the above-described polymer film on the surface of the metal layer on the side in contact with the polymer film. In addition, it is preferable that the above-described interactable group is a group corresponding to the functional group of the compound having a functional group, which is contained in the above-described polymer film, such as an amino group and an epoxy group, and a hydroxy group and an epoxy group.

Examples of the interactable group include a group mentioned as the functional group in the above-described compound having a functional group.

Among these, as the interactable group, from the viewpoint of adhesiveness and ease of performing a treatment, a covalent-bondable group is preferable, an amino group or a hydroxy group is more preferable, and an amino group is particularly preferable.

The metal layer in the laminate according to the embodiment of the present disclosure may be a metal layer having a circuit pattern.

It is also preferable that the metal layer in the laminate according to the embodiment of the present disclosure is processed into, for example, a desired circuit pattern by etching to form a flexible printed circuit board. The etching method is not particularly limited, and a known etching method can be used.

### EXAMPLES

Hereinafter, the present disclosure will be described in more detail with reference to examples. The materials, the used amounts, the proportions, the treatment contents, the treatment procedures, and the like described in the following examples can be appropriately changed without departing from the gist of the present disclosure. Therefore, the scope of the present disclosure is not limited to the following specific examples.

<<Measurement Method>>

[Dielectric Loss Tangent]

The dielectric loss tangent was measured by a resonance perturbation method at a frequency of 10 GHz. A 10 GHz cavity resonator (“CP531” manufactured by Kanto Electronics Application & Development Inc.) was connected to a network analyzer (“E8363B” manufactured by Agilent Technology), a sample (width: 2.0 mm×length: 80 mm) of the polymer film or each layer was inserted into the cavity resonator, and the dielectric loss tangents of the polymer film and each layer were measured based on a change in resonance frequency for 96 hours before and after the insertion in an environment of a temperature of 25° C. and a humidity of 60% RH.

[Surface Coverage]

A polymer film not containing the compound having a functional group and a compound having a functional group were prepared. Surface energies of the polymer film not containing the compound having a functional group and the compound having a functional group were calculated. Similarly, surface energy of the polymer film to be measured was calculated.

Specifically, the surface energy was obtained by conditioning for 24 hours at 25° C. and a relative humidity of 60%, measuring the contact angle to water and methylene iodide, and calculating the surface energy using Owens method based on the measured contact angle.

A calibration curve was created using the surface energy of the polymer film not containing the compound having a functional group and the surface energy of the compound having a functional group.

From the created calibration curve, the surface coverage was calculated based on the surface energy of the polymer film to be measured.

[Peel Strength]

A peeling test piece with a width of 1.0 cm was produced from the laminate of the polymer film and the copper layer, the polymer film was fixed to a flat plate with double-sided adhesive tape, and the strength (kN/m) in a case of peeling the polymer film off from the copper layer in the laminate at a rate of 50 mm/min was measured by the 180° method in conformity with JIS C 5016 (1994).

<<Production Example>>

<Polymer Having Dielectric Loss Tangent of 0.005 or Less>

LC-A: Liquid crystal polymer produced by production method described below

-Production of LC-A-

940.9 g (5.0 mol) of 6-hydroxy-2-naphthoic acid, 377.9 g (2.5 mol) of 4-hydroxyacetaminophen, 415.3 g (2.5 mol) of isophthalic acid, and 867.8 g (8.4 mol) of acetic acid anhydride were added to a reactor provided with a stirrer, a torque meter, a nitrogen gas introduction pipe, a thermometer, and a reflux condenser, the gas inside the reactor was replaced with nitrogen gas, and the mixture was heated from room temperature (23° C.) to 140° C. over 60 minutes while being stirred in a nitrogen gas stream and was refluxed at 140° C. for 3 hours.

Thereafter, the mixture was heated from 150° C. to 300° C. over 5 hours while distilling off by-product acetic acid and unreacted acetic acid anhydride and maintained at 300° C. for 30 minutes, and the resultant was taken out from the reactor and cooled to room temperature. The obtained solid matter was crushed with a crusher, thereby obtaining powdery liquid crystal polyester (B1). The flow start temperature of the liquid crystal polyester (B1) was 193.3° C.

The liquid crystal polyester (B1) obtained above was heated from room temperature to 160° C. over 2 hours and 20 minutes in a nitrogen atmosphere, further heated from 160° C. to 180° C. over 3 hours and 20 minutes, maintained at 180° C. for 5 hours to carry out solid phase polymerization, cooled, and crushed with a crusher, thereby obtaining powdery liquid crystal polyester (B2). The flow start temperature of the liquid crystal polyester (B2) was 220° C.

The liquid crystal polyester (B2) obtained above was heated from room temperature (23° C.) to 180° C. over 1 hour and 25 minutes in a nitrogen atmosphere, further heated from 180° C. to 255° C. over 6 hours and 40 minutes, maintained at 255° C. for 5 hours to carry out solid phase polymerization, and cooled, thereby obtaining powdery liquid crystal polyester (LC-A). A flow start temperature of LC-A was 302° C. In addition, as a result of measuring a melting point of the LC-A using a differential scanning calorimetry device, the measured value was 311° C.

LC-B: Liquid crystal polymer produced by production method described below

-Production of LC-B-

940.9 g (5.0 mol) of 6-hydroxy-2-naphthoic acid, 377.9 g (2.5 mol) of 4-hydroxyacetaminophen, 415.3 g (2.5 mol) of isophthalic acid, and 867.8 g (8.4 mol) of acetic acid anhydride were added to a reactor provided with a stirrer, a torque meter, a nitrogen gas introduction pipe, a thermometer, and a reflux condenser, the gas inside the reactor was replaced with nitrogen gas, and the mixture was heated from room temperature (23° C.) to 143° C. over 60 minutes while being stirred in a nitrogen gas stream and was refluxed at 143° C. for 1 hour.

Thereafter, the mixture was heated from 150° C. to 300° C. over 5 hours while distilling off by-product acetic acid and unreacted acetic acid anhydride and maintained at 300° C. for 30 minutes, and the resultant was taken out from the reactor and cooled to room temperature. The obtained solid matter was crushed with a crusher, thereby obtaining powdery liquid crystal polyester (B1).

The liquid crystal polyester (B1) obtained above was heated from room temperature to 160° C. over 2 hours and 20 minutes in a nitrogen atmosphere, further heated from 160° C. to 180° C. over 3 hours and 20 minutes, maintained at 180° C. for 5 hours to carry out solid phase polymerization, cooled, and crushed with a crusher, thereby obtaining powdery liquid crystal polyester (B2).

The liquid crystal polyester (B2) obtained above was heated from room temperature (23° C.) to 180° C. over 1 hour and 20 minutes in a nitrogen atmosphere, further heated from 180° C. to 240° C. over 5 hours, maintained at 240° C. for 5 hours to carry out solid phase polymerization, and cooled, thereby obtaining powdery liquid crystal polyester (LC-B).

LC-C: Liquid crystal polymer produced by production method described below

-Production of LC-C-

941 g (5.0 mol) of 6-hydroxy-2-naphthoic acid, 273 g (2.5 mol) of 4-aminophenol, 415 g (2.5 mol) of isophthalic acid, and 1123 g (11 mol) of acetic acid anhydride were added to a reactor provided with a stirrer, a torque meter, a nitrogen gas introduction pipe, a thermometer, and a reflux condenser, the gas inside the reactor was replaced with nitrogen gas, and the mixture was heated from room temperature (23° C.) to 150° C. over 15 minutes while being stirred in a nitrogen gas stream and was refluxed at 150° C. for 3 hours.

Thereafter, the mixture was heated from 150° C. to 320° C. over 3 hours while distilling off by-product acetic acid and unreacted acetic acid anhydride and maintained until an increase in viscosity was observed, and the resultant was taken out from the reactor and cooled to room temperature. The obtained solid matter was crushed with a crusher, thereby obtaining powdery liquid crystal polyester (C1).

The liquid crystal polyester (C1) obtained above was maintained at 250° C. for 3 hours in a nitrogen atmosphere to carry out solid phase polymerization, cooled, and crushed with a crusher, thereby obtaining powdery liquid crystal polyester (LC-C).

<Polyphenylene Ether>

P-1: Mixture of pellets of commercially available polyphenylene ether (SA120, manufactured by SABIC; weight-average molecular weight Mw: 2,600)/bisphenol A-type epoxy resin (EPICLON 850S, manufactured by DIC Corporation; average number of epoxy groups: 2)/bisphenol A-type cyanate ester resin (Badcy, manufactured by LONZA KK.)/aromatic condensed phosphate ester (PX-200, manufactured by DAIHACHI CHEMICAL INDUSTRY CO., LTD.)/tris(diethylphosphinyloxy) aluminum (EXOLIT OP-935, manufactured by CLARIANT Japan)/zinc octoate=25/34/25/8/8/0.01 (mass ratio)

<Compound Having Functional Group>

Any one of the following polymers A-1 to A-5 was used in a mass ratio shown in Table 1.

[Production of Polymer A-1]

-Synthesis of Monomer 1-

In a 100 mL eggplant flask, 5.0 g of 1,1-dimethoxycyclohexane, 9.0 g of 2-hydroxymethacrylate, 25.0 g of 1H,1H,2H,2H-perfluorooctanol, 0.87 g of pyridinium paratoluenesulfonate, and 30 mL of toluene were weighed, and the mixture was stirred at 40° C. for 1 hour and then stirred at 40° C. for 4 hours under a reduced pressure of 100 mmHg. The obtained reaction solution was cooled to room temperature (23° C.) and washed separately with saturated sodium hydrogen carbonate aqueous solution, and the obtained organic layer was dried over anhydrous magnesium sulfate, concentrated, and subjected to silica gel column chromatography, thereby obtaining 8.0 g of a monomer 1 represented by the following formula as a colorless liquid (yield: 40%).

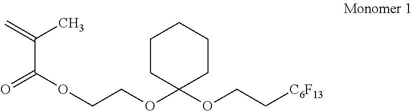

-Synthesis of Monomer 2-

Into a 2,000 mL three-neck flask equipped with a stirring blade, a thermometer, and a dropping funnel, 100 g of 2-hydroxyethyl methacrylate and 240 mL of N,N-dimethylacetamide (DMAc) were charged, and cooled in an ice bath. Next, 126.8 g of 3-chloropropionyl chloride was added dropwise thereto, and the mixture was stirred under ice-cooling for 3 hours. The obtained reaction solution was cooled to room temperature and washed separately with 1 mol/L hydrochloric acid in 1,000 mL of ethyl acetate, saturated sodium hydrogen carbonate aqueous solution, and water, and the obtained organic layer was dried over anhydrous magnesium sulfate and concentrated, thereby obtaining 85 g of a target monomer 2 as a pale yellow liquid (yield: 88%).

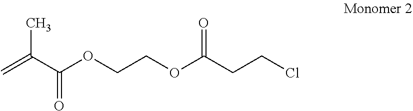

-Synthesis of polymer A-1-

2.34 g of the monomer 1, 3.60 g of CYCLOMER M100 (manufactured by Daicel Corporation), 4.05 g of the monomer 2, 18.57 g of methyl ethyl ketone (MEK), and 3.760 g of dimethyl 2,2′-azobis(isobutyrate) (polymerization initiator, manufactured by FUJIFILM Wako Chemicals Corporation) were weighed, and the mixture was stirred at 70° C. for 6 hours.

After the reaction, reprecipitation was carried out using 500 mL of methanol. The obtained solid was dissolved in 15 g of MEK, 5.57 g of triethylamine and 0.01 g of p-methoxyphenol were added thereto, and the mixture was stirred at 60° C. for 4 hours. The reaction solution was allowed to return to room temperature, reprecipitated using 500 mL of methanol, and dissolved in 25 g of MEK, thereby obtaining 5.1 g a polymer A-1 (yield: 53%).

In the following reaction formula, “M100” represents CYCLOMER M100. In addition, the unit of the content (content ratio) of each constitutional unit in the polymer is “% by mole”.

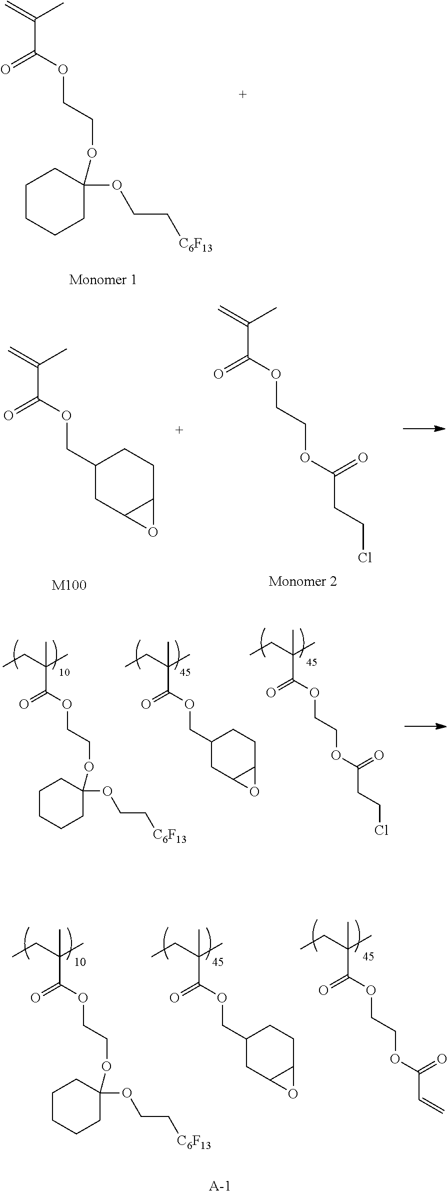

[Production of Polymer A-2]

-Synthesis of Monomer 3-

Using (3-mercaptopropyl)trimethoxysilane and 2-(perfluorohexyl)ethylvinyl ether (CHEMINOX FAVE-6 (UNIMATEC CO., LTD.)), a monomer 3 was synthesized according to the method described in Tetrahedron, 1991, 47, pp. 4927 to 4940. In the following structural formula, Et represents an ethyl group.

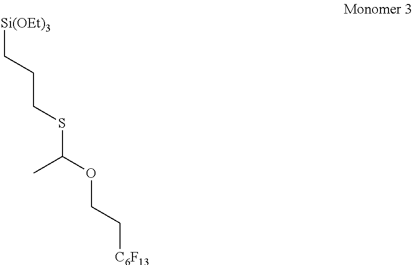

-Synthesis of Polymer A-2-

3.90 g of the monomer 3, 6.59 g of 3-glycidoxypropyltrimethoxysilane (manufactured by FUJIFILM Wako Chemicals Corporation), 6.93 g of 3-methacryloxypropyltrimethoxysilane (manufactured by FUJIFILM Wako Chemicals Corporation), 50 g of acetone, 1.38 g of a 5% potassium carbonate aqueous solution, and 9.0 g of pure water were weighed, and the mixture was stirred at 50° C. for 5 hours. The obtained reaction solution was cooled to room temperature, and 50 g of methyl isobutyl ketone (MIBK) and 50 g of 5% saline solution were added thereto to extract an organic layer. The organic layer was further washed once with 50 g of 5% saline solution and twice with 50 g of pure water, and 10 g of magnesium sulfate and 0.01 g of p-methoxyphenol were added thereto. After filtering off the magnesium sulfate, the solvent was distilled off at 50° C. under reduced pressure of 35 mmHg, thereby obtaining 20.2 g of a polymer A-2 as a 60.5% by mass MIBK solution (yield: 95%).

In the following structural formula, Me represents a methyl group and Et represents an ethyl group. In addition, the unit of the content (content ratio) of each constitutional unit in the polymer is “% by mole”.

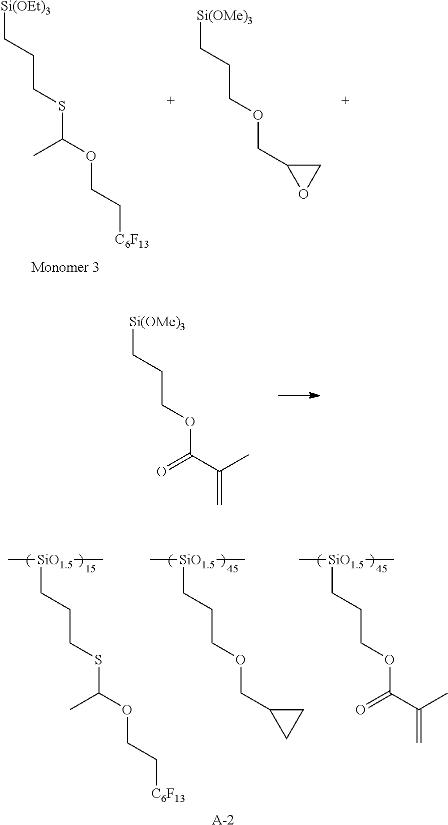

[Production of Polymer A-3]

A polymer A-3 was produced in the same manner as in the polymer A-1, except that, in the production of the polymer A-1, 25.0 g of 1H,1H,2H,2H-perfluorooctanol, which was used in the synthesis of the monomer 1, was changed to 18.1 g of 1H,1H,2H,2H-perfluorohexanol.

[Production of Polymer A-4]

A polymer A-4 was produced in the same manner as in the polymer A-2, except that, in the production of the polymer A-2, 2-(perfluorohexyl)ethylvinyl ether (CHEMINOX FAVE-6 (manufactured by UNIMATEC CO., LTD.)), which was used in the synthesis of the monomer 3, was changed to 2-(perfluorobutyl)ethylvinyl ether (CHEMINOX FAVE-4 (manufactured by UNIMATEC CO., LTD.)).

[Production of Polymer A-5]

-Synthesis of polymer A-5-

2.34 g of the monomer 1, 3.60 g of CYCLOMER M100 (manufactured by Daicel Corporation), 4.05 g of the monomer 2, 18.57 g of methyl ethyl ketone (MEK), and 3.760 g of dimethyl 2,2′-azobis(isobutyrate) (polymerization initiator, manufactured by FUJIFILM Wako Chemicals Corporation) were mixed with each other, and the mixture was stirred at 70° C. for 6 hours.

After the reaction, reprecipitation was carried out using 500 mL of methanol. The obtained solid was dissolved in 15 g of MEK, and 5.57 g of triethylamine and 0.01 g of p-methoxyphenol were added thereto. Thereafter, the mixture was heated to 60° C., and a solution consisting of 6.12 g of tetraethyleneglycol bis(3-mercaptopropionate) (EGMP-4, manufactured by SC Organic Chemical Co., Ltd.) and 6.12 g of MEK, which had been prepared separately, was added thereto over 2 hours. Further, the reaction solution was stirred at 60° C. for 4 hours, allowed to return to room temperature, and reprecipitated using 500 mL of methanol. The obtained solid was dissolved in 25 g of MEK to obtain a polymer A-5.

A difference between an SP value of the LC-A, LC-B, or LC-C described above and an SP value of the polymer A-1, the polymer A-2, the polymer A-3, the polymer A-4, or the polymer A-5 (compound having a functional group) was all 5 MPa^{0.5} or less.

<Third Component>

C-1: The following mixture was used as a third component C-1 in a mass ratio shown in Table 1.
Tricyclodecanedimethanol diacrylate (A-DCP, manufactured by Shin-Nakamura Chemical Co., Ltd.; polyfunctional monomer): 46 parts by mass
IRGACURE 290 (manufactured by BASF): 3 parts by mass

A difference between an SP value of C-1 and an SP value of the LC-A, LC-B, or LC-C described above was all 5 MPa^{0.5} or less.

[Filler]

F-1: Liquid crystal polymer particles produced by production method described below

-Production of LC-D-

1034.99 g (5.5 mol) of 2-hydroxy-6-naphthoic acid, 378.33 g (1.75 mol) of 2,6-naphthalenedicarboxylic acid, 83.07 g (0.5 mol) of terephthalic acid, 272.52 g (2.475 mol; 0.225 mol excess with respect to the total molar amount of 2,6-naphthalenedicarboxylic acid and terephthalic acid) of hydroquinone, 1226.87 g (12 mol) of acetic acid anhydride, and 0.17 g of 1-methylimidazole as a catalyst were added to a reactor provided with a stirrer, a torque meter, a nitrogen gas introduction pipe, a thermometer, and a reflux condenser. After the gas in the reactor was replaced with nitrogen gas, the mixture was heated from room temperature to 145° C. over 15 minutes while being stirred in a nitrogen gas stream and was refluxed at 145° C. for 1 hour.

Next, the mixture was heated from 145° C. to 310° C. over 3 hours 30 minutes while distilling off by-product acetic acid and unreacted acetic acid anhydride and maintained at 310° C. for 3 hours, and solid liquid crystal polyester (LC-D) was taken out and cooled to room temperature. A flow start temperature of the polyester (LC-D) was 265° C.

-Production of Liquid Crystal Polymer Particles (F-1)-

Using a jet mill (“KJ-200” manufactured by KURIMOTO Ltd.), the liquid crystal polyester (LC-D) was crushed to obtain fine particles of liquid crystal polyester (liquid crystal polymer particles (F-1)). An average particle diameter of the fine particles of liquid crystal polyester was 9 μm.

F-2: Commercially available silica fine particles having an average particle diameter of 0.5 μm (SO-C2, manufactured by Admatechs) were used so that the amount of solid content was the amount shown in Table 1.

F-3: Copolymer particles of ethylene tetrafluoride and perfluoroalkoxy ethylene (PFA) (melting point: 280° C., average particle diameter: 0.2 μm to 0.5 μm, dielectric loss tangent: 0.001)

F-4: Commercially available hollow powder having an average particle diameter of 16 μm (glass bubbles iM30K, manufactured by 3M Japan Limited)

F-5: Boron nitride particles (melting point >500° C., HP40MF100 (manufactured by Mizushima Ferroalloy Co., Ltd.), dielectric loss tangent: 0.0007)

(Examples 1 to 20 and Comparative Example 1)

<Film Formation>

The method shown in Table 1 was selected from among the following multilayer coatings A and B, single layer coating, and co-casting.

[Multilayer Coating A]

-Preparation of Polymer Solution-

The polymer having a dielectric loss tangent of 0.005 or less was added to N-methylpyrrolidone, and the mixture was stirred at 140° C. for 4 hours in a nitrogen atmosphere to dissolve the polymer. Thereafter, the compound having a functional group and the third component were optionally added so as to have the mass ratios shown in Table 1, and the mixture was stirred at 25° C. for 30 minutes to obtain each polymer solution. A concentration of solid contents of the polymer solution for the layer A (core layer) was 10% by mass, and a concentration of solid contents of the polymer solution for the layer B (surface layer) was 5% by mass.

Subsequently, first, the polymer solution was allowed to pass through a sintered fiber metal filter having a nominal pore diameter of 5 μm and allowed to pass through a sintered fiber metal filter having the same nominal pore diameter of 5 μm, thereby obtaining a polymer solution for the layer A and a polymer solution for the layer B.

In a case where the additive was not dissolved in N-methylpyrrolidone, a liquid crystal polymer solution was prepared without adding the additive, the mixture was allowed to pass through the above-described sintered fiber metal filter, and then the additive was added thereto and stirred.

-Production of Film-

The obtained polymer solution for the layer A (core layer) and the obtained polymer solution for the layer B (surface layer) were fed to a slot die coater equipped with a slide coater, and applied onto a treated surface of a copper foil (manufactured by FUKUDA METAL FOIL & POWER CO., LTD., CF-T9DA-SV-18, thickness: 18 μm) such that a film having a three-layer configuration (surface layer/core layer/surface layer) was formed. The polymer solution was dried at 40° C. for 4 hours to remove the solvent from the coating film and obtain a polymer film.

[Multilayer Coating B]

-Preparation of Polymer Solution-

The polymer shown in Table 1 and the additive shown in Table 1 were added to toluene such that the concentration of solid contents was 80%, and the mixture was stirred for 60 minutes to obtain polymer solutions for the layer A and the layer B, respectively.

-Production of Film-

The polymer solutions for the layer A and the layer B were fed to a slot die coater equipped with a slide coater, and applied onto a treated surface of a copper foil (manufactured by FUKUDA METAL FOIL & POWER CO., LTD., CF-T9DA-SV-18, thickness: 18 μm, surface roughness Rz of a treated surface: 0.85 μm) for multilayer coating. After drying at 100° C. for 3 minutes, the coating film was dried at 170° C. for 3 minutes to remove the solvent from the coating film. Thereafter, the temperature was raised from room temperature to 200° C. at 1° C./min, and a heat treatment was performed at the temperature for 2 hours to obtain a polymer film (laminate) having a copper layer.

[Single Layer Coating]

-Preparation of Polymer Solution-

The polymer having a dielectric loss tangent of 0.005 or less was added to N-methylpyrrolidone, and the mixture was stirred at 140° C. for 4 hours in a nitrogen atmosphere to dissolve the polymer. Thereafter, the compound having a functional group and the third component were added so as to have the mass ratios shown in Table 1, and the mixture was stirred at 25° C. for 30 minutes to obtain a polymer solution. The concentration of solid contents was 10% by mass.

In a case where the additive was not dissolved in N-methylpyrrolidone, a liquid crystal polymer solution was prepared without adding the additive, the mixture was allowed to pass through the above-described sintered fiber metal filter, and then the additive was added thereto and stirred.

Subsequently, first, the solution was allowed to pass through a sintered fiber metal filter having a nominal pore diameter of 5 μm and allowed to pass through a sintered fiber metal filter having the same nominal pore diameter of 5 μm, thereby obtaining a polymer solution.

-Production of Film-

The obtained polymer solution was fed to a slot die coater, and applied onto a treated surface of a copper foil (manufactured by FUKUDA METAL FOIL & POWER CO., LTD., CF-T9DA-SV-18, thickness: 18 μm) for coating. The polymer solution was dried at 40° C. for 4 hours to remove the solvent from the coating film and obtain a polymer film.

[Co-Casting]

-Preparation of Polymer Solution-

The polymer shown in Table 1 was added to N-methylpyrrolidone, and the mixture was stirred at 140° C. for 4 hours in a nitrogen atmosphere to form a solution, and allowed to pass through a sintered fiber metal filter having a nominal pore diameter of 10 μm first and allowed to pass through a sintered fiber metal filter having the same nominal pore diameter of 10 μm again. Subsequently, the additive shown in Table 1 was added so as to have the mass ratio shown in Table 1, and the mixture was stirred at 25° C. for 30 minutes to obtain a polymer solution.

In a case where the additive was not dissolved in N-methylpyrrolidone, a liquid crystal polymer solution was prepared without adding the additive, the mixture was allowed to pass through the above-described sintered fiber metal filter, and then the additive was added thereto and stirred.

-Production of Film-

The obtained polymer solution for the layer A and the obtained polymer solution for the layer B were fed to a casting die equipped with a multi-manifold adapted for co-casting a three-layer configuration (layer B/layer A/layer B), and cast onto a treated surface of a copper foil (manufactured by FUKUDA METAL FOIL & POWER CO., LTD., CF-T9DA-SV-18, thickness: 18 μm, surface roughness Rz of a surface to be attached (treated surface): 0.85 μm). The polymer solution was dried at 60° C. for 4 hours to remove the solvent from the casting film and obtain a polymer film.

<Polymerization Reaction>

With regard to the polymer film including C-1 as the third component, after the drying is completed, an air-cooled metal halide lamp (manufactured by Eye Graphics Co., Ltd.) was used to radiate ultraviolet rays at an irradiation amount of 300 mJ/cm2 to polymerize the polyfunctional monomer (polyfunctional reactive compound) in C-1 and form a three-dimensional crosslinking structure. Therefore, the polymer film included a cured substance of the polyfunctional monomer.

<Production of Copper-Clad Laminated Plate>

[Metal Layer Forming Step]

-Copper-Clad Laminated Plate Precursor Step-

A copper foil (manufactured by FUKUDA METAL FOIL & POWER CO., LTD., CF-T9DA-SV-18, thickness: 18 μm) was placed on the polymer film to be in contact with the polymer film, and using a laminator (“Vacuum laminator V-130” manufactured by Nikko-Materials Co., Ltd.), lamination was performed for 1 minute under conditions of 140° C. and a laminating pressure of 0.4 MPa, thereby obtaining a copper-clad laminated plate precursor.

-Main Thermocompression Step-

Using a thermocompression machine (“MP-SNL” manufactured by Toyo Seiki Seisaku-sho, Ltd.), the obtained copper-clad laminated plate precursor was subjected to thermocompression under conditions of 300° C. and 4.5 MPa for 10 minutes to produce a copper-clad laminated plate (laminate).

-Annealing Step-

The obtained copper-clad laminated plate was further heated from room temperature (25° C.) to 280° C. at 1° C./min in a nitrogen atmosphere. A heat treatment was performed at 280° C. for 2 hours to obtain a copper-clad laminated plate (laminate).

<<Evaluation>>

The produced polymer film was evaluated by the methods described above, and the results are shown in Table 1.

TABLE 1

| | Layer A (core layer) | | | | | | | | | | Layer B (surface layer) | | | | | | | | | | |
|---|---|---|---|---|---|---|---|---|---|---|---|---|---|---|---|---|---|---|---|---|---|
| | | | | Compound | | | | | | | | | | Compound | | | | | | | |
| | Polymer having dielectric | | | having | | | | | | | Polymer having dielectric | | | having | | | | | | Evaluation result | |
| | loss tangent of 0.005 | | | functional | | Third | | | | | loss tangent of 0.005 | | | functional | | Third | | | | Polymer | |
| | or less | | | group | | component | | Filler | | | or less | | | group | | component | | | | film | |
| | | Dielectric | Content | | Content | | Content | | Content | | | Dielectric | Content | | Content | | Content | Thick- | Film | Dielectric | Laminate |
| | | loss | (% by | | (% by | | (% by | | (% by | Thickness | | loss | (% by | | (% by | | (% by | ness | formation | loss | Peel |
| | Type | tangent | mass) | Type | mass) | Type | mass) | Type | mass) | (μm) | Type | tangent | mass) | Type | mass) | Type | mass) | (μm) | method | tangent | strength |
| Example 1 | LC-A | 0.003 | 50 | A-1 | 1 | C-1 | 49 | — | — | 50 | — | — | — | — | — | — | — | — | Single layer | 0.009 | 1.0 kN/m |
| | | | | | | | | | | | | | | | | | | | conting | | |
| Example 2 | LC-A | 0.003 | 100 | — | — | — | — | — | — | 48 | LC-A | 0.003 | 50 | A-1 | 1 | C-1 | 49 | 5 | Multilayer | 0.003 | 1.2 kN/m |
| | | | | | | | | | | | | | | | | | | | coating A | | |
| Example 3 | LC-A | 0.003 | 100 | — | — | — | — | — | — | 40 | LC-A | 0.003 | 50 | A-2 | 1 | C-1 | 49 | 5 | Multilayer | 0.003 | 1.2 kN/m |
| | | | | | | | | | | | | | | | | | | | coating A | | |
| Comparative | LC-A | 0.003 | 100 | — | — | — | — | — | — | 40 | LC-A | 0.003 | 100 | — | — | — | — | 5 | Multilayer | 0.003 | 0.2 kN/m |
| Example 1 | | | | | | | | | | | | | | | | | | | coating A | | |
| Example 4 | LC-B | 0.004 | 25 | — | — | — | — | F-1 | 75 | 22 | LC-B | 0.004 | 50 | A-3 | 1 | C-1 | 49 | 3 | Co-casting | 0.002 | 0.6 kN/m |
| Example 5 | LC-B | 0.004 | 25 | — | — | — | — | F-1 | 75 | 48 | LC-B | 0.004 | 50 | A-3 | 1 | C-1 | 49 | 3 | Co-casting | 0.002 | 0.7 kN/m |
| Example 6 | LC-B | 0.004 | 25 | — | — | — | — | F-1 | 75 | 45 | LC-B | 0.004 | 50 | A-3 | 0.5 | C-1 | 49.5 | 5 | Co-casting | 0.002 | 0.7 kN/m |
| Example 7 | LC-B | 0.004 | 25 | — | — | — | — | F-1 | 75 | 45 | LC-B | 0.004 | 75 | A-3 | 1 | C-1 | 24 | 5 | Co-casting | 0.002 | 0.8 kN/m |
| Example 8 | LC-B | 0.004 | 25 | — | — | — | — | F-1 | 75 | 45 | LC-B | 0.004 | 50 | A-3 | 1 | C-1 | 49 | 5 | Co-casting | 0.002 | 0.8 kN/m |
| Example 9 | LC-B | 0.004 | 25 | — | — | — | — | F-1 | 75 | 45 | LC-B | 0.004 | 25 | A-3 | 1 | C-1 | 74 | 5 | Co-casting | 0.002 | 0.7 kN/m |
| Example 10 | LC-B | 0.004 | 25 | — | — | — | — | F-1 | 75 | 55 | LC-B | 0.004 | 50 | A-3 | 1 | C1 | 49 | 5 | Co-casting | 0.002 | 0.9 kN/m |
| Example 11 | LC-B | 0.004 | 25 | — | — | — | — | F-1 | 75 | 45 | LC-B | 0.004 | 50 | A-3 | 3 | C1 | 47 | 5 | Co-casting | 0.002 | 0.9 kN/m |
| Example 12 | LC-B | 0.004 | 25 | — | — | — | — | F-1 | 75 | 45 | LC-B | 0.004 | 50 | A-4 | 1 | C1 | 49 | 5 | Co-casting | 0.002 | 0.8 kN/m |
| Example 13 | LC-B | 0.004 | 25 | — | — | — | — | F-1 | 75 | 45 | LC-B | 0.004 | 50 | A-5 | 1 | C-1 | 49 | 5 | Co-casting | 0.002 | 0.8 kN/m |
| Example 14 | LC-B | 0.004 | 50 | — | — | — | — | F-2 | 50 | 45 | LC-B | 0.004 | 50 | A-3 | 1 | C-1 | 49 | 5 | Co-casting | 0.003 | 0.9 kN/m |
| Example 15 | LC-B | 0.004 | 25 | — | — | — | — | F-3 | 75 | 45 | LC-B | 0.004 | 50 | A-3 | 1 | C-1 | 49 | 5 | Co-casting | 0.002 | 0.8 kN/m |
| Example 16 | LC-B | 0.004 | 50 | — | — | — | — | F-4 | 50 | 45 | LC-B | 0.004 | 50 | A-3 | 1 | C-1 | 49 | 5 | Co-casting | 0.002 | 0.8 kN/m |
| Example 17 | LC-B | 0.004 | 50 | — | — | — | — | F-5 | 50 | 45 | LC-B | 0.004 | 50 | A-3 | 1 | C-1 | 49 | 5 | Co-casting | 0.002 | 0.8 kN/m |
| Example 18 | LC-C | 0.004 | 25 | — | — | — | — | F-1 | 75 | 45 | LC-B | 0.004 | 50 | A-3 | 1 | C-1 | 49 | 5 | Co-casting | 0.002 | 0.8 kN/m |
| Example 19 | LC-B | 0.004 | 25 | — | — | — | — | F-1 | 75 | 45 | LC-C | 0.004 | 49.5 | A-3 | 1 | C-1 | 49.5 | 5 | Co-casting | 0.002 | 0.8 kN/m |
| Example 20 | P-1 | 0.005 | 50 | — | — | — | — | F-2 | 50 | 45 | P-1 | 0.005 | 99 | A-3 | 1 | — | — | 5 | Multilayer | 0.003 | 1.1 kN/m |
| | | | | | | | | | | | | | | | | | | | coating B | | |

The polymer films of Examples 1 to 20 were a polymer film in which the concentration of the compound having a functional group in the surfaces on both sides thereof was higher than in the inside. In addition, it was confirmed that, in the polymer film of Example 2, the surface coverage of the compound having a functional group in the surfaces on both sides thereof was 100% by area.

On the other hand, the polymer film of Comparative Example 1 did not contain the compound having a functional group, and there was no difference in concentration between the surface and the inside.

In addition, in the polymer films of Examples 1 and 3, the surface coverage of the compound having a functional group in the surfaces on both sides thereof was 50% by area or more.

On the other hand, in the polymer film of Comparative Example 1, the surface coverage of the compound having a functional group on any surface was 0% by area.

From the results shown in Table 1, the polymer films of Examples 1 to 20, which are the polymer film according to the embodiment of the present disclosure, were excellent in adhesiveness with the substrate than the polymer film of Comparative Example 1.

On the other hand, the polymer film of Comparative Example 1, which did not contain the compound having a functional group, the peel strength was insufficient and the adhesiveness with the substrate was deteriorated.

In addition, from the results shown in Table 1, the polymer films of Examples 1 to 19, which are the polymer film according to the embodiment of the present disclosure, were a polymer film having a low dielectric loss tangent.

What is claimed is:

1. A polymer film comprising:
a polymer having a dielectric loss tangent of 0.005 or less; and
a compound having a functional group,
wherein a concentration of the compound having a functional group is higher on at least one surface of the polymer film than inside of the polymer film.

2. A polymer film comprising:
a polymer having a dielectric loss tangent of 0.005 or less; and
a compound having a functional group,
wherein a surface coverage of the compound having a functional group on at least one surface of the polymer film is 50% by area or more.

3. The polymer film according to claim 1,
wherein the compound having a functional group contains a silicon atom or a fluorine atom.

4. The polymer film according to claim 1, further comprising:
a third component in which the compound having a functional group is immobilized to the polymer having a dielectric loss tangent of 0.005 or less.

5. The polymer film according to claim 4,
wherein the third component includes a cured substance of a polyfunctional reactive compound.

6. The polymer film according to claim 4,
wherein the third component contains a polymer which has a functional group interacting with the compound having a functional group and is compatible with the polymer having a dielectric loss tangent of 0.005 or less.

7. The polymer film according to claim 1,
wherein a difference between an SP value of the polymer having a dielectric loss tangent of 0.005 or less, which is determined by Hoy method, and an SP value of the compound having a functional group, which is determined by Hoy method, is 5 MPa^{0.5} or less.

8. The polymer film according to claim 1,
wherein the polymer film includes a layer A and a layer B on at least one surface of the layer A, and
the layer B contains the compound having a functional group.

9. The polymer film according to claim 8,
wherein the layer B contains a third component in which the compound having a functional group is immobilized to the polymer having a dielectric loss tangent of 0.005 or less.

10. The polymer film according to claim 9,
wherein a content of the third component in the layer B is higher than a content of the third component in the layer A.

11. The polymer film according to claim 8,
wherein the polymer film further includes a layer C, and
the layer B, the layer A, and the layer C are provided in this order.

12. The polymer film according to claim 1, further comprising:
a filler.

13. The polymer film according to claim 12,
wherein a number density of the filler is higher inside the polymer film than on a surface of the polymer film.

14. The polymer film according to claim 1,
wherein the polymer having a dielectric loss tangent of 0.005 or less includes a liquid crystal polymer.

15. The polymer film according to claim 14,
wherein the polymer having a dielectric loss tangent of 0.005 or less includes a liquid crystal polymer having a constitutional unit represented by any of Formulae (1) to (3),
—O-Ar¹-CO— Formula (1)
—CO-Ar²-CO— Formula (2)
—X-Ar³-Y— Formula (3)
in Formulae (1) to (3), Ar¹ represents a phenylene group, a naphthylene group, or a biphenylylene group, Ar² and Ar³ each independently represent a phenylene group, a naphthylene group, a biphenylylene group, or a group represented by Formula (4), X and Y each independently represent an oxygen atom or an imino group, and hydrogen atoms in Ar¹ to Ar³ may be each independently substituted with a halogen atom, an alkyl group, or an aryl group,
-Ar⁴-Z-Ar⁵- Formula (4)
in Formula (4), Ar⁴ and Ar⁵ each independently represent a phenylene group or a naphthylene group, and Z represents an oxygen atom, a sulfur atom, a carbonyl group, a sulfonyl group, or an alkylene group.

16. A polymer film comprising:
a liquid crystal polymer; and
a compound having a functional group,
wherein a concentration of the compound having a functional group is higher on at least one surface of the polymer film than inside of the polymer film, or
wherein a surface coverage of the compound having a functional group on at least one surface of the polymer film is 50% by area or more.

17. A laminate comprising:
the polymer film according to claim 1; and
a metal layer disposed on a surface in which a concentration of the compound having a functional group in the polymer film is higher than inside of the polymer film.

18. The laminate according to claim 17,
wherein the metal layers are respectively disposed on both surfaces of the polymer film.

19. The laminate according to claim 17,
wherein the metal layer is a copper layer, and
a peel strength between the polymer film and the copper layer is 0.5 kN/m or more.

20. The laminate according to claim 17,
wherein the polymer film includes a layer A and a layer B on at least one surface of the layer A,
the layer B contains the compound having a functional group, and
the metal layer is disposed on the layer B.
